(19) United States
(12) Patent Application Publication
(10) Pub. No.: US 2026/0123387 A1
(43) Pub. Date: Apr. 30, 2026

(54) BACK SIDE WAFER-SCALE INTEGRATION WITH MODULAR POWER DELIVERY

(71) Applicant: Volantis Semiconductor, Inc., Portland, OR (US)

(72) Inventors: Kevin Nan Lam, Pleasanton, CA (US); Tapabrata Ghosh, Oakland, CA (US)

(73) Assignee: Volantis Semiconductor, Inc., Portland, OR (US)

(21) Appl. No.: 18/940,944

(22) Filed: Nov. 8, 2024

Related U.S. Application Data
(60) Provisional application No. 63/714,353, filed on Oct. 31, 2024.

(51) Int. Cl. H01L 23/528; G02B 6/42; H01L 23/00; H01L 23/14; H01L 23/498; H01L 25/065; H05K 1/18; H05K 7/14

(52) U.S. Cl. CPC H10W 20/427; G02B 6/4274; H05K 1/181; H05K 7/14329; H10W 70/65; H10W 70/69; H10W 90/401; H10W 90/00; H10W 90/724

(57) ABSTRACT

Techniques for power delivery are disclosed. A wafer-scale silicon interposer (WSSI) is accessed. A front side of the WSSI is bonded to a plurality of functional chips. The WSSI includes a plurality of through-silicon vias (TSVs). A plurality of modular power substrates (MPSs) is attached to a back side of the WSSI. Each MPS is coupled to one or more functional chips within the plurality of functional chips. The plurality of MPSs is mechanically connected to one or more control circuits. The one or more control circuits include a plurality of DC-to-DC power converters. The one or more control circuits send DC power to the plurality of MPSs. The sending includes a first voltage conversion. The DC power that was sent is transferred, by the plurality of MPSs, to the plurality of functional chips. The transferring is based on the plurality of TSVs.

### RELATED APPLICATIONS

This application claims the benefit of U.S. provisional patent application “Cooling for Wafer-Scale Integration With Back Side Power Coupling” Ser. No. 63/714,353, filed Oct. 31, 2024. The foregoing application is hereby incorporated by reference in its entirety.

### FIELD OF ART

This application relates generally to power delivery and more particularly to back side wafer-scale integration with modular power delivery.

### BACKGROUND

Circuit designers for a long time hypothesized that multiple electronic circuits could be formed within a single electronic device. The single electronic device could be smaller, cooler, and faster than the large, hot, and power hungry vacuum tube-based circuits of old. The multiple circuits would be formed in a single active area. If this hypothesis were true, then electronic circuits could be formed from multiple, “solid state” devices such as transistors. To do so, electric isolation of the transistors was critical. P-N junction isolation was developed for effectively separating circuits on a semiconducting crystal such as silicon since a p-n junction could prevent current flow across the junction. Therefore, the p-n junctions could be used to isolate the transistors from each other. The individual transistors could be wired together to form basic logic circuits, and the basic logic circuits could themselves be combined to form more complex logic circuits. The combining can be repeated to achieve electronic systems such as microprocessors. The microprocessors could be programmed to perform a wide variety of processing tasks.

Increasing the number of circuit elements or devices fabricated in a single chip has been and remains a highly desirable goal. The increased number of circuit elements enables processing architectures based on reduced instruction sets, parallelism, etc., that can be used to increase processing speed. New fabrication techniques have enabled smaller devices, increased wiring densities, and better handled current leakage and noise. To increase device count, a designer can reduce device size, increase chip size, or both. Moore's Law postulates that the number of transistors in an integrated circuit doubles approximately every two years. However, there are physical limits to how small a device can be. For example, one cannot use less than a single electron to represent a logic value or a fraction of a molecule for an insulation layer. Similarly, increasing chip size has physical limitations. As the chip size increases, the chip will include more defects statistically. A defect can include a physical flaw at a site on the chip. Common defects can include cracks, variations in layer thickness, interstitial defects, vacancy defects, straight dislocations, and so on. Also, larger chips are prone to warping and fabricated layer variations. Fabrication defects can include misalignments, gaps in wiring, non-connecting contacts and vias, etc. When a defect is encountered within a given chip, the chip can fail, where a failure can include a chip that operates partially or not at all, operates out of design specifications, etc. Failed chips are identified as soon as possible during fabrication and are discarded. Substandard chips are identified and, in some cases, can be sold at a discounted price. The discounted price can reflect the diminished chip capabilities.

### SUMMARY

Businesses operators, researchers, scientists, and consumers have clamored for computers and consumer devices that are faster and have greater capabilities than similar devices from even a few years ago. In order to meet these market pressures, circuit designers have striven to design and fabricate integrated circuits with ever-increasing processing performance, expanded data processing options, and “nice to have” features. The latter now commonly include touch screens, cameras, speakers capable of spatial audio, and biometric sensing, to name only a few. However, increasing processing speed by introducing architectures for parallel processing, or including neural processors to help consumers find a particular photo within their vast photo collections, includes adding circuitry to the chips. To add new circuitry into chips, designers have two main options: increase the dimensions of a chip by making it larger, or increase circuit density by reducing feature sizes. Ideally, the chip would be the size of an entire wafer, and the feature sizes would include reduced wire widths and separation, smaller transistor sizes, minimum contact sizes, and reductions of any other dimension related to circuity.

Both of the options for producing more capable chips present difficult challenges. Foremost among the challenges of building larger chips, and especially wafer-scale chips, is the fact that physical defects are distributed across the entire wafer. So, as the chips become larger, the likelihood that more defects will be included in and will impact operation of a given larger chip increases significantly because the bigger chips will “capture” more defects. In addition, as the circuit feature sizes decrease, the probabilities of fabrication errors or defects being introduced during fabrication also increase. To counter the physical limitations that impact fabricating larger chips, techniques such as redundancy have been implemented. Multiple “copies” of a chiplet, core, or other blocks of circuitry are fabricated on the chips. Based on which copies function properly, the working copies are selected, while the nonfunctioning or substandard copies are switched out. This technique has been highly effective for memories, where circuit density and chip yield area challenge. However, fabricating chips with redundant elements consumes chip real estate that might be otherwise used to offer additional functions.

Increasing the number of circuit elements or devices fabricated in a single chip has been and remains highly desirable. New fabrication techniques have enabled smaller devices, increased wiring densities, and better handled negative side effects of smaller device sizes such as current leakage and switching noise. Yet, attaining wafer-scale integration has remained elusive. While Moore's Law has postulated that the number of transistors in an integrated circuit doubles approximately every two years, one cannot use less than a single electron to represent a logic value or a fraction of a molecule for an insulation layer. Similarly, increasing chip size has physical limitations. As the chip size increases, the chip will include more defects including cracks, layer thickness variations, interstitial defects, vacancy defects, straight dislocations, and so on. Further, larger chips are prone to warping and fabricated layer variations including misalignments, gaps in interconnect, open contacts and vias, etc. When a defect is encountered within a given chip, the chip can fail, operate outside of design specifications, etc. Failed chips are identified based on layer-by-layer testing and are discarded when identified.

Another issue associated with wafer-scale integration is dealing with heat. During operation, chips generate copious amounts of excess heat. A significant effect of the excess heat is that the chips, and the substrates or boards to which the chips are bonded, expand. However, the chips and substrates have different coefficients of thermal expansion, which cause the chips, substrates, etc. to expand by different amounts or displacements. Further, when substrates or boards are interconnected using mechanical connections, the substrates undergo different deflections that can cause disconnections from or damage to each other. To remedy this potentially disastrous situation, the mechanical connections between the substrates are configured to remain connected and reliable under the differences in displacements by accommodating a maximum lateral displacement of the substrates. The maximum lateral displacement is accommodated by rigid-flex connectors which remain connected even during lateral deflection.

Disclosed embodiments provide a method for power delivery comprising: accessing a wafer-scale silicon interposer (WSSI), wherein a front side of the WSSI is bonded to a plurality of functional chips, and wherein the WSSI includes a plurality of through-silicon vias (TSVs); attaching, to a back side of the WSSI, a plurality of modular power substrates (MPSs), wherein each MPS is coupled to one or more functional chips within the plurality of functional chips; connecting mechanically the plurality of MPSs, to one or more control circuits, wherein the one or more control circuits include a plurality of DC-to-DC power converters; sending DC power, by the one or more control circuits, to the plurality of MPSs, wherein the sending includes a first voltage conversion; and transferring the DC power that was sent, by the plurality of MPSs, to the plurality of functional chips, wherein the transferring is based on the plurality of TSVs.

Various features, aspects, and advantages of various embodiments will become more apparent from the following further description.

### BRIEF DESCRIPTION OF THE DRAWINGS

The following detailed description of certain embodiments may be understood by reference to the following figures wherein:

FIG. 1 is a flow diagram for back side wafer-scale integration with modular power delivery.

FIG. 2 is a flow diagram for transferring DC power.

FIG. 3 illustrates a wafer with multiple die.

FIG. 4 illustrates inter-die interconnect for wafer-scale integration.

FIG. 5 shows inter-die interconnect and redundancy for wafer-scale integration.

FIG. 6 illustrates an interposer and flip chips for wafer-scale integration.

FIG. 7 is a diagram of a wafer interposer with functional chips.

FIG. 8 is a diagram of a modular power substrate (MPS).

FIG. 9 is a diagram of a front side of a unified control board (UCB).

FIG. 10 is a diagram of a back side of a unified control board.

FIG. 11 is a diagram of a bus bar coupled to a UCB.

FIG. 12 is a cross-section of an apparatus for back side wafer-scale integration with modular power delivery.

FIG. 13 is an illustration of a neural network.

FIG. 14 is an example of training a neural network.

FIG. 15 is an example of enhancing memory bandwidth.

FIG. 16 is a cross-section of wafer scale integration for neural network memory bandwidth.

FIG. 17 is a system diagram for back side wafer-scale integration with modular power delivery.

### DETAILED DESCRIPTION

Techniques for back side wafer-scale integration with modular power delivery are disclosed. For decades, circuit designers have demanded integrated circuits or chips with larger dimensions and smaller feature sizes in order to include every circuit feature demanded for a given application. Ideally, an entire wafer would be used for a single integrated circuit, thereby enabling processor feature set enhancements and increased processing power. However, successfully building larger and larger chips has proven highly elusive for many practical reasons. Principal among the challenges of building larger chips, and particularly wafer-scale chips, is the fact that physical defects are distributed across a wafer on which the chips are fabricated. As the chips become larger, the probability that more defects will impact operation of the larger chip also increases, since bigger chips will capture more defects. In addition, as the circuit feature sizes, such as interconnect widths, contact sizes, active area sizes, gate widths, oxide thicknesses, and so on decrease, the probabilities of fabrication errors or defects also increase. To counter the physical limitations that characterize the fabricating of larger chips, techniques such as redundancy have been used. Multiple “copies” of a chiplet, core, and so on are fabricated on a chip. Based on which copies function properly, the working copies are selected, while the nonfunctioning or substandard copies are switched out. This technique has been highly effective for memories. However, fabricating chips with redundant elements consumes chip real estate that might be otherwise used to provide additional functions.

In disclosed techniques, a wafer-scale silicon interposer (WSSI) is used to accomplish wafer-scale integration for integrated circuits. The silicon interposer provides an array of interconnections that include through-silicon vias (TSVs). The TSVs provide connectivity between a front side and a back side of the WSSI. Functional integrated circuits, such as processors, multiprocessors, memories, and special-purpose integrated circuits including circuits for machine learning, can be bonded to the front side of the WSSI. The bonding can be accomplished using techniques such as micro-bump techniques. The WSSI can further provide layers of interconnect that can be used to enable connectivity between the functional chips.

Since the functional chips require power in order to operate, modular power substrates (MPSs) are attached to the back side of the WSSI. The modular power substrates provide DC power to the functional chips via the TSVs. The MPSs are in turn mechanically connected to control circuits, where the control circuits are provided by a unified control board (UCB). The mechanical connections are accomplished using a high voltage socket and rigid-flex strips. The high voltage socket and rigid-flex strips are used to maintain a reliable electrical connection between the MPSs and the UCB.

During operation, the functional chips and other electrical elements such as the DC-to-DC converters generate copious excess heat. A significant effect of the excess heat is that the heated elements expand. The functional chips that are bonded to the WSSI cause the WSSI to expand. Similarly, electrical elements, the MPSs, etc. connected to the unified control board (UCB) cause the UCB to expand. However, the WSSI and the UCB have different coefficients of thermal expansion, which causes the WSSI and the UCB to expand by different amounts or displacements. As a result, physical damage could be caused to WSSI and/or the UCB by introducing strains into the WSSI and the UCB. To remedy this potentially disastrous situation, the mechanical connections between the WSSI and the UCB are configured to remain connected and reliable under the differences in displacements by accommodating a maximum lateral displacement of the UCB. The maximum lateral displacement can be accommodated by the modularity of the MPSs, the high voltage socket, and the rigid-flex connectors associated with the MPSs.

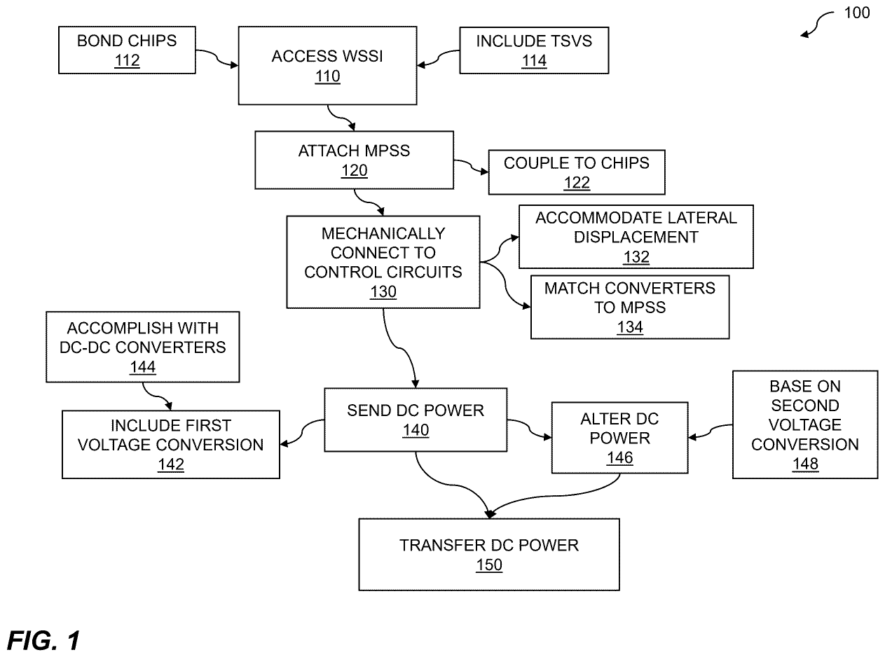

FIG. 1 is a flow diagram for back side wafer-scale integration with modular power delivery. The flow 100 includes accessing a wafer-scale silicon interposer (WSSI) 110. Wafer-scale integration has been a long-sought goal of integrated circuit design. Wafer-scale integration would enable use of an entire wafer such as a silicon wafer on which one, large integrated circuit could be fabricated. However, since physical defects in the silicon wafer are distributed across the wafer, portions of circuitry which were fabricated over the defects will likely not function properly. In addition, errors that occur when fabricating the many layers that form the integrated circuit further create portions of the integrated circuit that will likely not function. Instead, by attaching a plurality of integrated circuits to the WSSI, wafer-scale integration can be achieved. In this case, the wafer can be used as an interposer to couple the integrated circuits. The wafer can be a 300 mm wafer, a 200 mm wafer, or a wafer of another size. The wafer can comprise silicon or another suitable material. The wafer can include any amount of front-end-of-line (FEOL) processing and/or back-end-of line (BEOL) processing. The processing can be based on Complementary Metal-Oxide-Semiconductor (CMOS), Silicon on Insulator (SOI), or another process. In the flow 100, a front side of the WSSI is bonded 112 to a plurality of functional chips. The WSSI can have a front side and a back side onto which elements such as the functional circuit elements can be attached. The functional chips can include general purpose chips such as processor chips, multiprocessor chips, application-specific integrated circuits (ASICS), memory chips, and so on. The functional chips can further include specialty processing chips such as accelerators for artificial intelligence training and inferences. In the flow 100, the WSSI includes a plurality of through-silicon vias (TSVs) 114. A TSV can include an electrical connection that completely passes through a wafer such as a silicon wafer or a die. The plurality of TSVs is oriented vertically in order to enable connections between the front side of the wafer and the back side of the wafer. Chips such as the functional chips can be positioned such that connections to the chips align with the TSVs. In some examples, a wafer can be ground to enable TSV processing with repeatable shapes and parasitic characteristics.

The flow 100 includes attaching 120, to a back side of the WSSI, a plurality of modular power substrates (MPSs). A modular power substrate can include one or more electrical elements, connectors, and so on. In embodiments, the attaching is based on one or more controlled collapse chip connection bumps (C4s). In the C4 technique, solder balls are placed on connections or pads at the topmost layer of the functional chips. The chips are flipped using a flip-chip technique so that the C4 bumps align with the TSVs. The electrical elements can include DC-to-DC converters. Any number of voltage conversions can be included so that the functional chips receive power at an appropriate voltage for functionality. In embodiments, the first voltage conversion is accomplished by the plurality of DC-to-DC power converters. The connectors can include a high-power connector and a plurality of rigid-flex strips. The substrate associated with an MPS to which the electrical elements, connectors, and so on are mounted can include a variety of materials. In embodiments, one or more MPSs within the plurality of MPSs comprise an organic substrate. An organic substrate can be based on organic materials such as organic materials used to manufacture printed circuit boards. The organic substrate materials can include paper cores impregnated with phenolic resin; woven or unwoven glass cloth impregnated with epoxy or cyanate ester among others; natural fibers; etc. In other embodiments, one or more MPSs within the plurality of MPSs comprise an inorganic substrate. An inorganic substrate can be based on silicon, glass with a similar coefficient of expansion to the MPS, etc. In the flow 100, each MPS is coupled to one or more functional chips 122 within the plurality of functional chips. The coupling between each MPS and the one or more functional chips can be accomplished using the TSVs.

In embodiments, the plurality of MPSs is based on a form factor mirroring one or more corresponding functional chips, within the plurality of functional chips, on the front side of the WSSI. The form factor can include a square form factor, a rectangular form factor, and so on. In a usage example, the form factor of the MPS is smaller than the form factor of the WSSI. The flow 100 includes connecting mechanically 130 the plurality of MPSs to one or more control circuits, wherein the one or more control circuits include a plurality of DC-to-DC power converters. The connecting mechanically can be accomplished using plug-and-socket connectors, terminals, cables, and so on. In a usage example, the connecting mechanically an MPS to a control circuit can be accomplished using a DC power connector and a plurality of rigid-flex strips. In embodiments, the connecting mechanically is based on a high voltage socket. The control circuits can include digital control circuits. The digital control circuits can be controlled by a processor, a multiprocessor, a microcontroller, and so on. In embodiments, the one or more control circuits comprise one or more control boards. The one or more control boards can be connected to the one or more MPSs. In embodiments, the one or more control boards comprise a unified control board (UCB). The unified control board can include one or more MPSs within the plurality of MPSs. The UCB can include one or more digital control circuits. Note that the functional chips, electrical elements, etc. can generate prodigious excess heat while operating. The excess heat can be removed in order to protect chips such as the functional chips.

In the flow 100, the connecting mechanically accommodates a maximum lateral displacement 132 of the UCB due to thermal expansion during operation. Physical components such as substrates, WSSIs, etc. can expand when heated based on a coefficient of thermal expansion associated with each material. In embodiments, a coefficient of thermal expansion of the UCB is different than a coefficient of thermal expansion of the WSSI. The difference in expansion coefficients can cause connectors to disconnect, C4s to crack, physical strain within materials that can cause damage, etc. Thus, if the UCB is directly mechanically connected to a WSSI, the lateral displacement due to differences in thermal expansion can cause mechanical failure. Recall that the MPSs can be modular and based on a form factor mirroring one or more corresponding functional chips on the front side of the WSSI. The modularity of the MPSs can provide a flexible power delivery system to the functional chips which can accommodate different movements of the WSSI and UCB due to thermal expansion. For example, an MPS at one side of the WSSI can be decoupled from an MPS on the other side of the WSSI, thus accommodating various movements across the WSSI and UCB. Recall also that the MPSs can be mechanically connected to the UCB via a high-power socket, which can couple the DC-to-DC converters within the UCB to the MPSs. The high-power socket can provide flexibility to accommodate lateral movement between the UCB and the MPS (which is attached to the WSSI). Further, recall that the mechanical connection can include one or more rigid-flex strips, which can couple power control signals, power, and the like on the UCB to the MPSs. The flexibility of the rigid-flex strips can further accommodate lateral movement between the UCB and MPS. These mechanical connections can provide flexibility to accommodate local expansion. These factors can allow the MPSs to provide “flex” between the UCB and WSSI as they expand at different rates.

The flow 100 further includes matching 134 each DC-to-DC power converter within the plurality of DC-to-DC power converters included on the UCB to one or more respective MPSs in the plurality of MPSs. The matching can be accomplished by placing the one or more DC-to-DC converters on a side of the UCB opposite to the side of the UCB to which the MPSs are mounted. Interconnection between the DC-to-DC converters matched with one or more respective MPSs can be accomplished using interconnect associated with the UCB.

The flow 100 includes sending DC power 140, by the one or more control circuits, to the plurality of MPSs. The control circuits, which can be a UCB, can send DC power to all of the MPSs, to a subset of the MPSs, and so on. The DC power that is sent can include a range for the DC voltage. The range of DC voltage can include a percentage of a target voltage, an allowable operating range of DC voltage, and the like. In a usage example, the voltage range can include 48 volts to 54 volts, inclusive. In the flow 100, the sending includes a first voltage conversion 142. The first voltage conversion can include a DC-to-DC voltage conversion. The result of the DC-to-DC voltage conversion can include a DC voltage higher than the input DC voltage or a DC voltage lower than the input DC voltage. In the flow 100, the first voltage conversion is accomplished using the one or more DC-to-DC converters 144. The DC-to-DC converters can include a plurality of DC-to-DC converters connected to the UCB. In embodiments, the sending includes altering 146, by the plurality of MPSs, the DC power that was sent, wherein the altering is based on a second voltage conversion. The altering can be accomplished using one or more converters such as DC-to-DC converters. The altering can produce a voltage that can be used directly to operate one or more functional chips. In the flow 100, the altering is based on a second voltage conversion 148. The second voltage conversion can be accomplished using DC-to-DC converters associated with the MPSs. The second voltage conversion can attain a voltage less than the voltage resulting from the first voltage conversion. In embodiments, the second voltage conversion results in a voltage less than a threshold. The threshold can include a target voltage, an operating voltage, and so on. In embodiments, the threshold is 1 volt. For example, the second voltage conversion can result in a voltage of 0.85 volts to drive core logic elements. Functional chips can require additional voltages for I/O as well as for powering logical elements. Thus, the altering can produce an additional voltage output. The additional voltage output can be above or below the voltage less than a threshold. For example, the additional voltage output can be 1.2 volts to supply a voltage for I/O circuits.

The flow 100 includes transferring the DC power 150 that was sent, by the plurality of MPSs, to the plurality of functional chips, wherein the transferring is based on the plurality of TSVs. The one or more functional chips can obtain the transferred power from the TSVs. The functional chips can also use the TSVs to receive and send data, instructions, control signals, etc.

Various steps in the flow 100 may be changed in order, repeated, omitted, or the like without departing from the disclosed concepts. Various embodiments of the flow 100 can be included in a computer program product embodied in a non-transitory computer readable medium that includes code executable by one or more processors.

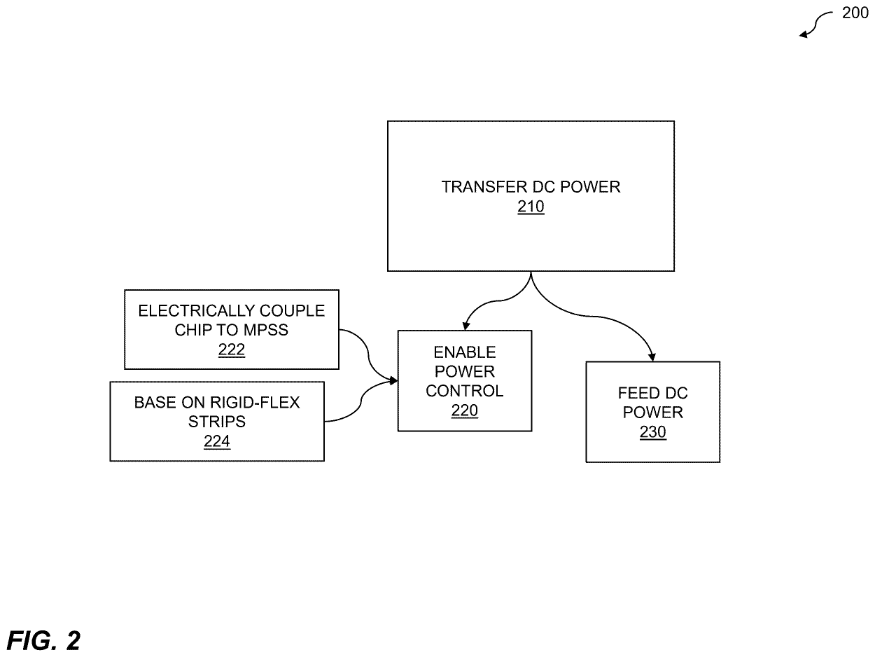

FIG. 2 is a flow diagram for transferring DC power. DC power can be transferred between elements bonded, connected, and otherwise attached to a wafer. The wafer can include an inorganic wafer such as a silicon wafer, a glass wafer, and so on. The wafer can include an interposer such as a silicon interposer or a glass interposer. The DC power can be transferred by a plurality of modular power substrates (MPSs) to a plurality of functional chips. The functional chips can include processors, multiprocessors, chips for specific processing applications such as machine learning, and so on. Discussed previously and throughout, the transferring the DC power can be accomplished based on a plurality of through-silicon vias (TSVs) implemented through the wafer. As the functional chips operate, the chips can generate copious heat. The heat can be transferred away from the functional chips using forced air or gas, liquid, convection, and the like. The heat causes the functional chips, a substrate or intercessor to which the chips are mounted, the MPSs, and so on to expand based on a coefficient of thermal expansion. Since the coefficients of thermal expansion can be different, the MPSs, for example, can include a form factor. The form factor can be smaller than that of the interposer. If the form factors of the MPSs are smaller than the wafer interposer, then the maximum lateral displacement of the MPS relative to the interposer can be reduced. The reduced lateral displacement can reduce the risk of loosening mechanical connections, potentially damaging functional chips, MPSs, or the interposer due to strains induced for the differing coefficients of thermal expansion, etc. Thus, the transferring DC power enables back side wafer-scale integration with modular power delivery.

A wafer-scale silicon interposer (WSSI) is accessed. A front side of the WSSI is bonded to a plurality of functional chips, and the WSSI includes a plurality of through-silicon vias (TSVs). A plurality of modular power substrates (MPSs) is attached to a back side of the WSSI. Each MPS is coupled to one or more functional chips within the plurality of functional chips. The plurality of MPSs is mechanically connected to one or more control circuits. The one or more control circuits include a plurality of DC-to-DC power converters. The one or more control circuits send DC power to the plurality of MPSs. The sending includes a first voltage conversion. The DC power that was sent is transferred, by the plurality of MPSs, to the plurality of functional chips. The transferring is based on the plurality of TSVs.

The flow 200 includes transferring DC power 210. The DC power that is transferred can include power that can be sent by one or more control circuits. In embodiments, the one or more control circuits comprise one or more control boards. In further embodiments, the one or more control boards comprise a unified control board (UCB). Recall that the control circuits can send DC power to a plurality of MPSs. The control circuits, which can be a UCB, can send DC power from one or more DC-to-DC converters to the plurality of modular power substrates (MPS). The MPSs can be attached to a back side of a wafer scale integration (WSI) interposer such as a wafer-scale integration silicon interposer (WSSI). The sending the power can include a first voltage conversion. The voltage conversion can include a DC-to-DC conversion accomplished by the DC-to-DC converters associated with the UCB. The transferring the DC power that was sent can be accomplished by the plurality of MPSs. The DC power is transferred to the plurality of functional chips, where the functional chips can be bonded to a front side of the WSSI. A variety of techniques can be used for transferring the DC power between the back side of the WSSI and the front side of the WSSI, such as the use of interconnect. The interconnect can include multilayer interconnect. In embodiments, the transferring is based on the plurality of TSVs. The TSVs enable an interconnecting path from the back side of the WSSI, through the WSSI, to the top side of the WSSI.

The flow 200 further includes enabling power control 220, by a digital controller chip, of the plurality of MPSs. The digital control chip can be mounted to the control circuits, control boards, or UCB. The digital controller chip can include a digital controller chip within a plurality of digital controller chips. The digital controller chip can be controlled by a processor, a multiprocessor, a microcontroller, and so on. The digital controller chip can enable or disable power such as DC power to any of the MPSs coupled to the UPS. The digital controller chip can control an input voltage to a DC-to-DC converter, the ratio of conversion by the DC-to-DC converter, the output voltage from the DC-to-DC converter, and so on. The flow 200 further includes electrically coupling 222 the digital controller chip to the plurality of MPSs, wherein the coupling is based on a plurality of rigid-flex strips. The digital controller chip and the plurality of MPSs can be electrically coupled using plug-and-socket techniques, cables, locking connectors, and so on. In the flow 200, the electrically coupling is based on a plurality of rigid-flex strips 224. The rigid-flex strips can enable a reliable connection between the digital controller chip and the MPSs even while experiencing differences in lateral displacement of the UCB and/or WSSI. The UCB can expand laterally due to heating of the UCB by operating elements such as DC-to-DC converters, digital controller chips, and so on. The rigid-flex strips can be used to provide control signals, data such as sensor data, instructions, and so on. In embodiments, the plurality of rigid-flex strips includes one or more power control signals. The one or more power control signals can include enabling or disabling one or more DC-to-DC converters, controlling DC-to-DC converter output voltages, and the like. The rigid-flex strips can be used for power transfer. In embodiments, the plurality of rigid-flex strips includes at least a portion of the DC power that was transferred. Another portion of the DC power can be transferred using a DC power connector associated with the MPSs.

Power such as DC power is provided to be converted by the DC-to-DC converters. The converted DC power can be used to operate the plurality of functional chips. The flow 200 further includes feeding the DC power 230, by one or more high current bus bars, to the UCB. The MPSs, the functional chips, digital controller chips, etc., when considered together, can consume tens, hundreds, or more amperes of current. In order to handle the amount of current drawn by the various elements, the high current bus bars can be used. The high current bus bars can include one or more of positive DC power bus bars and negative DC power bus bars. The bus bars can be coupled to a UCB so that elements such as DC-to-DC converters that are mounted to the UCB can access positive DC power and negative DC power from the bus bars. The bus bars can be secured with one or more brackets such as one or more insulating brackets. The insulating bracket can hold the bus bars in position and can secure the bus bars to the UCB. In embodiments, a voltage range of the DC power that was fed comprises a first voltage range. The voltage range can include a range of voltage values, a percentage of a target voltage, a voltage threshold, a voltage tolerance, and so on. In embodiments, the first voltage range includes 48 volts to 54 volts, inclusive.

Various steps in the flow 200 may be changed in order, repeated, omitted, or the like without departing from the disclosed concepts. Various embodiments of the flow 200 can be included in a computer program product embodied in a non-transitory computer readable medium that includes code executable by one or more processors.

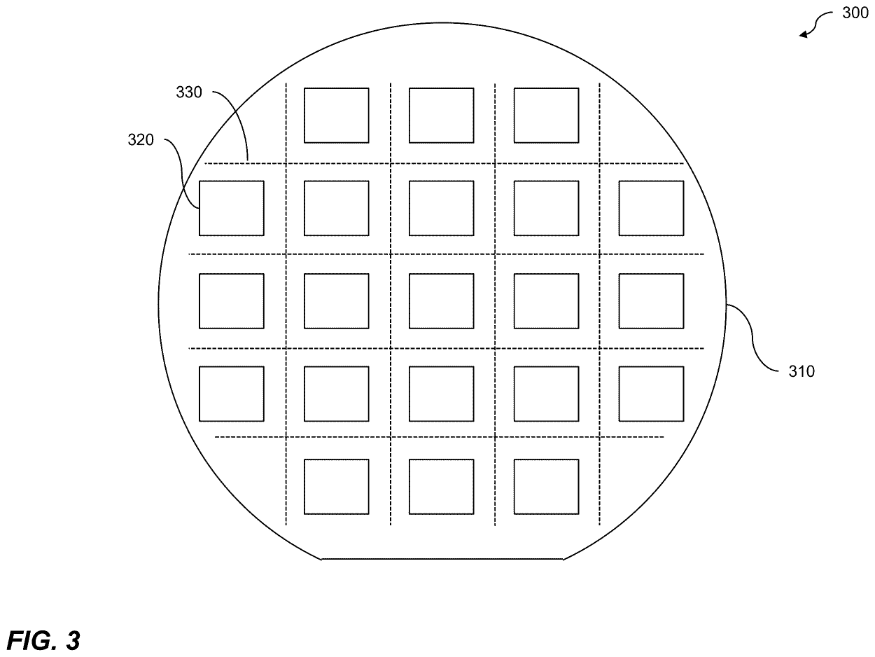

FIG. 3 illustrates a wafer with multiple die. A semiconductor wafer such as a silicon wafer is used in the fabrication of electronic circuits or chips. Other semiconductor materials such as germanium, silicon carbide, indium phosphide, etc. can also be used. The wafers that are used are obtained in various sizes. One common size wafer includes a 300 mm silicon wafer. Integrated circuits or “chips” are fabricated on the surface of the wafer. The circuits are called “die” during fabrication. The die can include a plurality of similar circuits or can include two or more different circuits or “projects”. The similar circuits and the different projects can include processors, memories, mix-signal chips, and so on.

The illustration 300 shows a wafer with multiple die. A wafer can be based on a monocrystalline semiconductor material. The semiconductor material can include a group IV material such as silicon, a groups III-V material such as gallium arsenide, and so on. The die on the wafer shown are substantially similar in size. However, the die can be substantially different in size. A system can depend on a certain number of functional die. For instance, an artificial accelerator used for training a large neural network can require a large number of functional die which can be AI accelerators. Since a wafer will contain defects randomly distributed across the wafer, some of the die fabricated on the wafer will be affected by the wafer defects and will not function properly. By fabricating multiples of the die, the probability of fabricating at least one functioning chip increases. Further, because presence or absence of circuits or die on the wafer can influence successful fabrication of a given die, a wafer can be “covered” with circuits for fabrication. Because of the shape of the wafer, which is typically round with at least one flat section to aid alignment, some of the circuits may not be fully contained within the boundaries of the wafer. The resulting “partial” circuits or die will not function fully or at all. In some cases, the partial die may be usable in other applications.

A wafer 310 is shown. The wafer can include multiple die such as die 320. The multiple die can be replicas of the same chip. In some cases, the multiple die can be different die, such as SRAM die. The die on the wafer can be all fabricated using the same fabrication technology. If any die requires different fabrication technologies, then that die must be fabricated on a different wafer. While 18 die are shown on wafer 310, in practice any number of die can be present. The number of die will depend on the size of the wafer and the size of the die. When fabrications steps, of which there can be many, are completed, the dies can be separated. The figure shows a plurality of dashed lines such as line 330. The dashed lines represent scribe lines or kerf associated with the wafer. In a typical process, a saw can be used to slice the wafer to liberate the individual die from the wafer. Since the saw has a finite width, some wafer material is lost due to the width of the saw. As a result, any structures such as test structures used to track processing steps during fabrication are lost.

While multiple die are shown in the diagram, the desire to further push the size of individual die has continued at a rapid pace. As one reference point, a packaged processor chip that is larger than 35 mm on a side has become common. However, as die on a wafer become larger, the risk of individual die being impacted by defects in the wafer or defects associated with any of the many fabrication step increases. How, then, could one produce even larger chips? One suggestion that has long been proposed is to use the “entire” wafer to form a single large chip or “super chip”. In addition to producing the one chip on the wafer, packaging could potentially be reduced since the packaging would involve the one chip instead of a typical suite of chips, where each chip requires its own packaging. Wafer scale integration or WSI has been proposed as particularly well suited to applications that demand extensive, demanding data processing. Examples proposed that could benefit from WSI have included computer architectures appropriate for massively parallel supercomputers, and computationally intensive applications such as machine learning and deep learning. However, successful fabrication of a single chip across an entire wafer is an extremely difficult undertaking. Noted above, the widespread and random distribution of defects and other variations such as warpage across a wafer render the ability to build one “super-circuit” elusive. Also, circuit redundancy becomes a major design issue. Not only are redundant circuits necessary that can be switched in to replace defective circuits, but the locations of the redundant circuits are also critical. Note that the redundant circuits must be connected in place of the defective circuits, and that wiring on an integrated circuit is extremely expensive in terms of real estate. As a result, the placement of the redundant circuits must be carefully considered to conserve wafer real estate and to reduce wiring complexity.

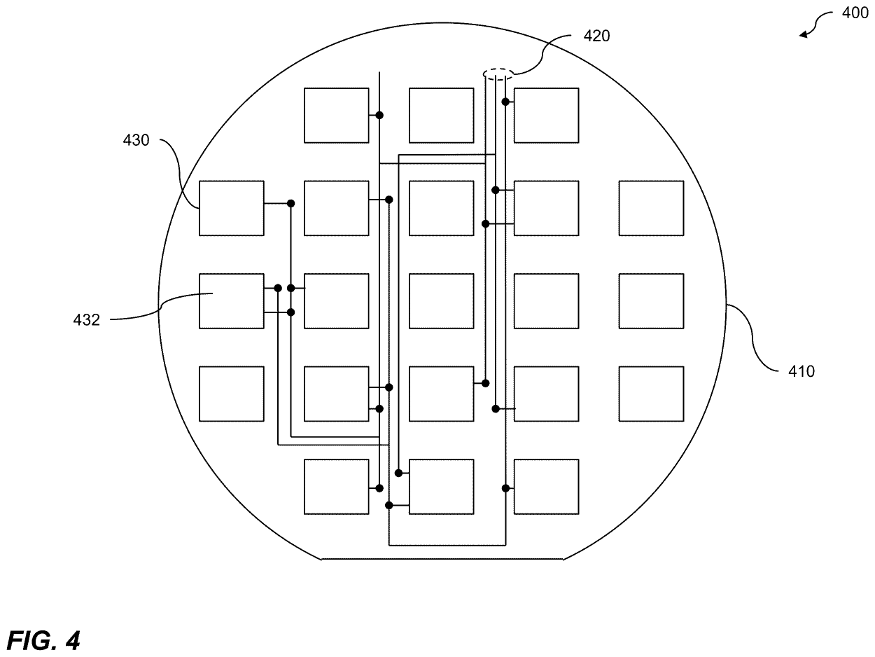

FIG. 4 illustrates inter-die interconnect for wafer-scale integration. Discussed previously and throughout, the desire for larger integrated circuits that can meet increasingly intensive processing demands has been stymied by the difficulty of producing large, single chips. One of the fundamental difficulties of producing a large chip, such as a wafer-sized chip, is that defects are randomly distributed across a wafer on which the large chip would be produced. Further, defects, such as disconnects in wiring, variations in oxide (insulator) thicknesses, open-circuit contacts, varying doping profiles, and so on, can be introduced during the fabrication process. One possible approach to “wafer-scale” integration is to continue to fabricate circuits on the wafer. Then, instead of cutting the wafer to access the individual dies, the wafer remains whole. By adopting an approach such as this one, the kerf, previously lost to the cutting of the wafer into the individual die, can be used for interconnect. Recall that interconnect on a wafer consumes wafer real estate that cannot be used for circuitry. By capturing the real estate previously lost to the kerf, additional wafer real estate is made available for interconnect. The interconnect in the kerf is particularly appropriate for long-haul connections, such as connections between individual die on the wafer.

The FIG. 400 illustrates use of wafer real estate otherwise lost to scribe lines or kerf for inter-die interconnect for wafer-scale integration. A wafer 410 is shown on which multiple die, or chips, are distributed. The die are fabricated together on the wafer. That is, each of the die on the wafer is fabricated based on the same processing steps. Since the individual die will not be separated from the wafer using a cutting technique, the kerf area of the wafer can be used for interconnect. Other areas of the die can also be used or interconnect. The interconnect 420 can be placed in wiring channels or routes, where the wiring channels are realized in what would formerly have been the kerf. The wiring channels include wafer real estate in which interconnecting wire can be placed. The interconnect can be fabricated while the various die on the wafer are fabricated. The interconnect can include a plurality of wiring layers. The various layers can be interconnected using contacts, vias, and so on. In the figure, a few example interconnecting runs are shown. The various die on the wafer can make connections to the wiring channels. In the figure, die 430 can use the wiring channels to connect to die 432.

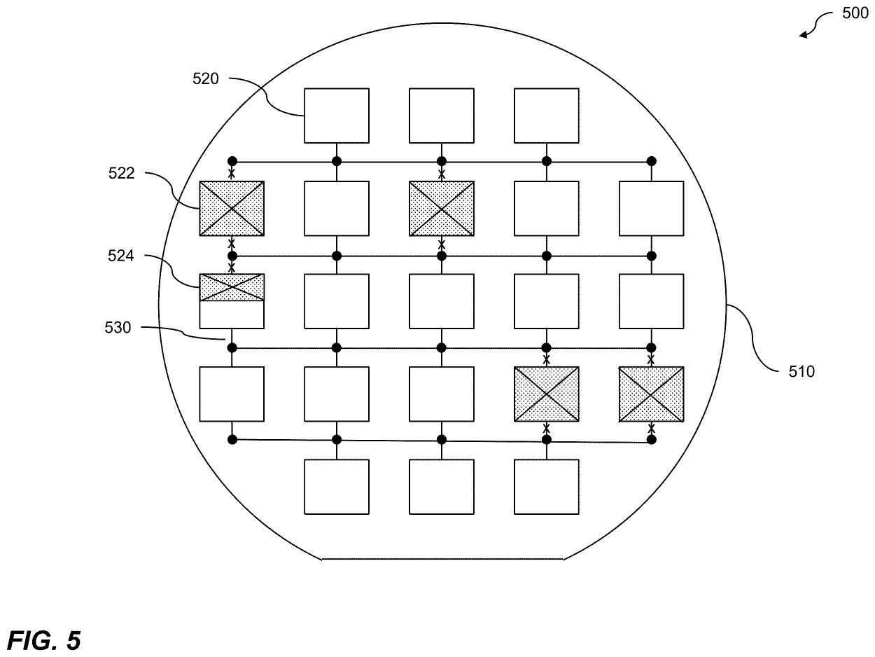

FIG. 5 shows inter-die interconnect and redundancy for wafer-scale integration. Building on the previous discussions of fabricating redundant die on a wafer and of using the kerf for interconnect, a technique for wafer-scale integration (WSI) can be based on fabricating redundant die on the wafer and selecting the working die for use by a system based on WSI. Working die can be selected while non-working die, partial die, and other substandard die can be electrically ejected from the system by deselecting them. The deselecting can include disabling wired connections to the unused die, physically “blowing” connections to the unused die, and so on. The remaining functioning die can be interconnected using inter-die interconnect to form a system on the wafer. Power can be provided to the die, as can data, control signals, and so on. In embodiments, the power to the die can be provided using modular power delivery techniques.

The showing 500 shows redundant die and inter-die interconnect. A wafer is shown 510. The wafer is populated with multiple die 520. A number of the die shown can be redundant. Some of the redundant die will include defects, can miss specifications, or can otherwise fail. The defects can be associated with the wafer on which the die are fabricated, associated with one or more processing steps for fabricating the die, and so on. This can result in die that are not operational, such as die 522. Recall that die can be fabricated on the wafer in order to ease some fabrication complexities, and that some of the added die can include partial die such as die 524. The failed die and the partial die can be excluded from a system formed by wafer-scale integration (WSI). In some cases, a die such as 524 can be partially functioning. The portion of the die that is functioning can be included in the WSI, while the portion of the die that is not functioning can be excluded. The functioning die can be inter-connected using inter-die interconnect 530. The inter-die interconnect can include multi-layer interconnect. The inter-die interconnect can be placed between the die associated with the multiple projects. Functioning die can be connected to the inter-die interconnect, and non-functioning die can be disconnected from the inter-die inter-connect.

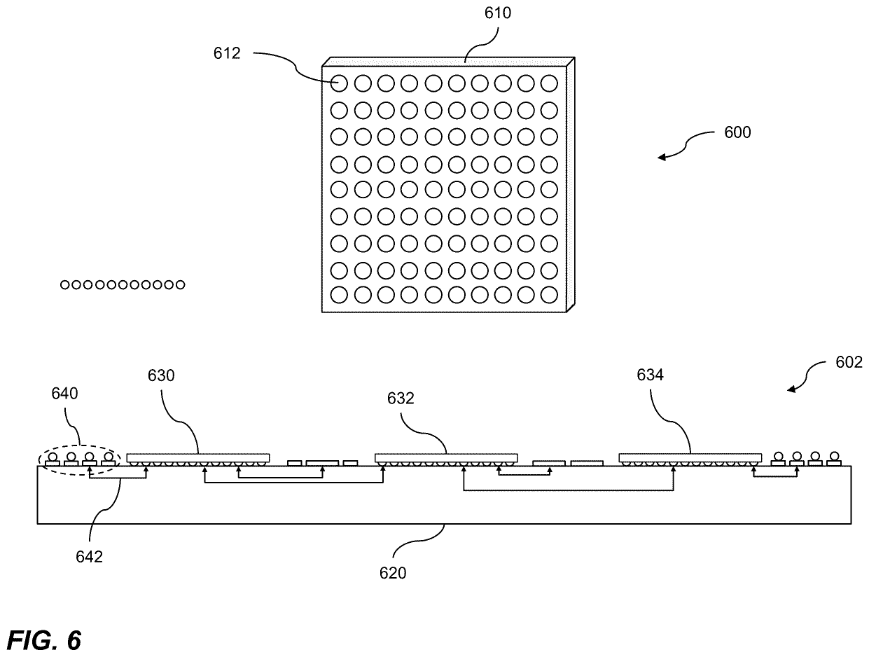

FIG. 6 illustrates an interposer and flip chips for wafer-scale integration. One technique that can be used to approach the benefits of wafer-scale integration is to attach more than one chip to a common substrate or interposer. The substrate can include a wafer, a carrier, a circuit board, and so on. To accomplish such a technique, all interconnections to a circuit or chip, including data connections, control and signal connections, and so on, can be made at the top layer of the chip. The connections at the top of the chip replace the traditional placement of pads at the periphery of the chip. To connect the top connections of the chip to the interposer, solder balls are placed on the top connections and the chip is “flipped” or inverted. The solder balls, when melted, can connect the top connections of the chip to corresponding connections or pads on the interposer. Additional chips can be similarly flipped and connected to additional corresponding connections on the interposer. The interposer can provide power to the plurality of flip-chips connected to it. The flip-chip technique is supported by power delivery provided by the interposer.

The illustration 600 includes an example flip-chip. Discussed previously, the flip-chip 610 differs from a traditional chip in that the connections to the flip-chip are made at the top of the chip rather than to pads located at the periphery of the chip. The top of a flip-chip is shown. The top can include pads that can be connected to pads corresponding to pads on a multi-chip module, a circuit board, an interposer, and so on. An example contact or pad 612 is shown. Multiple pads can be distributed across the top of the flip-chip. The pads can be oriented to correspond with receiving pads on the interposer. An array of pads is shown. In a usage example, a subset of pads is required to connect the flip-chip to the interposer. Thus, required pads are present at the top of the flip-chip, while the unused pads can be omitted from the top of the flip-chip.

The illustration 602 shows an example interposer. As discussed previously, the interposer 620 can include a wafer, a carrier, a circuit board, an interposer, and so on. One or more flip-chips can be attached to the interposer. In the figure, the flip-chips can include a first flip-chip 630, a second flip-chip 632, a third flip-chip 634, and so on. While three flip-chips are shown, other numbers of flip-chips can be attached to the interposer. In addition to serving as a landing spot for the flip-chips, the interposer can provide interconnect. The interconnect can be used to provide signals such as control signals, data, and so on to the flip-chips. The interconnect can further provide power to the flip-chips. Depending on the interposer used to receive the flip-chips, the interposer can include one or more layers of interconnect. The interconnect can include interconnect at a top surface of the interposer such as top surface interconnect 640. The interposer can further include additional layers of interconnect. The additional layers of interconnect can be fabricated on the interposer. The additional layers of interconnect can be isolated from each other using an insulating layer between the conducting interconnect layers. An example “lower layer” connection 642 is shown.

The use of flip-chips attached to an interposer can enable multichip module (MCM) techniques. A multichip module can refer to a substrate, carrier, circuit board, interposer, etc. onto which multiple ICs can be placed. The multiple ICs can be attached to the interposer, and the multiple ICs can be wired together using interconnect provided by the interposer. The interconnect associated with the interposer can provide power, control signals, and data between and among the ICs that are attached to the interposer. The power can be provided using modular power techniques. Depending on the particular type of MCM, the interposer can further include discrete components such as discrete resistors, discrete capacitors, discrete inductors, etc. The interposer further includes wiring for interconnecting ICs and the discrete components, if any. The MCM can be packaged and used as if it were a single IC on a board such as a circuit board within a system. MCMs have also been referenced as heterogeneous integration circuits and hybrid integrated circuits. A principal advantage of using MCMs is that multiple electronic components can be enclosed in a single “chip”, thereby improving modularity of a system design. Also, the use of MCMs can improve IC yields over ICs produced using monolithic IC design methodologies.

There can be several varieties of MCMs, where the MCM varieties are typically differentiated by size, complexity, design methodologies, and so on. At one end of the complexity scale, an MCM can include standard off-the-shelf ICs. The ICs can be attached to a circuit board such as a printed circuit board and can be used in place of an existing chip or package of chips. The printed circuit board can be designed to match the size pin-out of the existing chip or package of chips. An MCM can also be a highly complex element. The complex MCM can be based on one or more fully customized IC packages. The fully customized IC packages can be used to integrate multiple IC dies (e.g., unpackaged ICs) onto a substrate that provides interconnection among the dies. Because of the wiring requirements of the multiple IC dies, the substrate typically includes high density interconnection (HDI). The substrates that are used for the MCM can include thin films for interconnects (wires) and dielectrics (insulators); thick films that enable more than one layer of interconnect, and ceramic; and substrates that include laminates based on organics or plastics. The MCM based on thin films of interconnects and dielectrics can result in the highest circuit densities.

The MCM design concepts described previously suggest promising leads for implementing wafer-scale integration ICs. Multiple circuit dies could be fabricated within the same wafer. The wafer could further include built-in self-test (BIST), circuit redundancy to provide spare parts, and “self-rerouting” which can reroute around defective or failed elements and can wire in known good spare parts. In order to enable such capabilities, a significant number of interconnection layers would be required for WSI. Interconnect layer counts of approximately 10 layers have been predicted. In order to implement WSI in a cost-effective manner, several techniques have been proposed such as using an artificial neural network to develop a programmable topology, using a multichip-scale package, and so on.

Another technique that is being developed to enable wafer scale integration is based on the use of a silicon interposer, as discussed above. The silicon interposer, which can be a wafer, can be used to provide interconnections between a wide variety of components. The components include integrated circuits (chips), chiplets, power supplies, power converters, discrete electrical components, and so on. The interposer provides connection points that can be used to mechanically and electrically mount the chips, chiplets, etc. The interposer can be formed from inorganic materials such as glass or silicon, or organic materials such as those used to manufacture printed circuit boards. The electrical connections can be set to a pitch to simplify the attaching of the electrical elements. The electrical connections can be based on standardized manufacturing techniques such as using solder balls, micro-bumps, controlled collapse chip connection (C4) bumps, and electroplated bumps. The bumps on a chip are produced on the “top” side of a wafer (e.g., the non-substrate side) as a final processing step for the wafer. To mount the chips to the interposer, the chips are “flipped” using a flip-chip technique. The bumps at the top of the chips connect to pads on the interposer. The interposer can enable connections from the flip chip to a standard connection arrangement such as a grid. The interposer can further provide one or more layers of interconnect according to the process used to manufacture the wafer. Thus, higher densities, higher bandwidth, and faster speeds can be achieved. The layers of interconnect are used to provide power and ground, control signals, data, and so on.

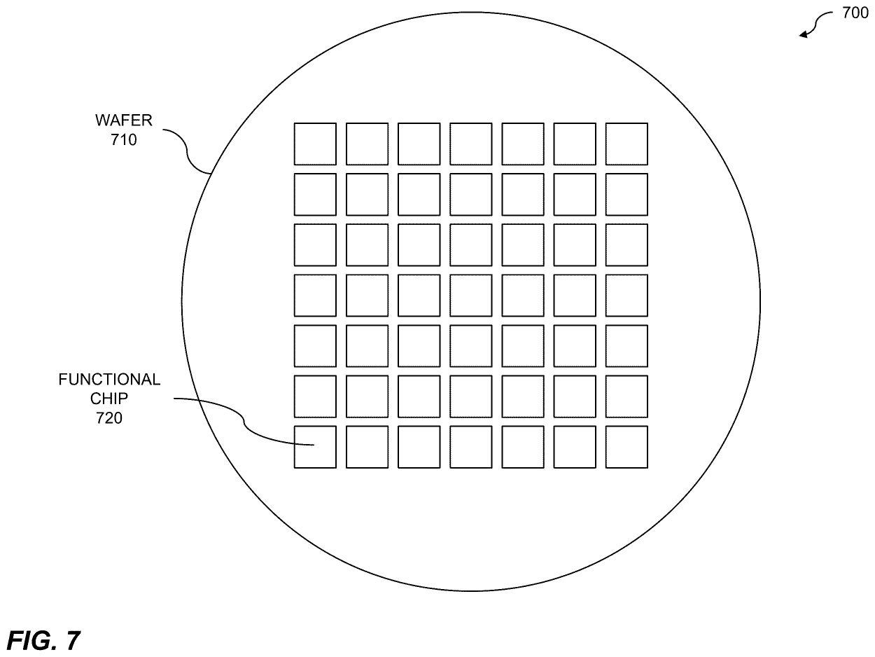

FIG. 7 is a diagram of a wafer interposer with functional chips 700. The wafer can include a semiconductor wafer, such as a silicon wafer, that can be used in traditional semiconductor manufacturing techniques. In addition to enable mounting of functional chips, the interposer can provide power to the functional chips mounted to the interposer. Power can be provided to the functional chips via the interposer from the opposite surface or side of the wafer. The wafer interposer enables back-side wafer-scale integration with modular power delivery. A wafer-scale silicon interposer (WSSI) is accessed. A front side of the WSSI is bonded to a plurality of functional chips, and the WSSI includes a plurality of through-silicon vias (TSVs). A plurality of modular power substrates (MPSs) is attached to a back side of the WSSI. Each MPS is coupled to one or more functional chips within the plurality of functional chips. The plurality of MPSs is mechanically connected to one or more control circuits. The one or more control circuits include a plurality of DC-to-DC power converters. The one or more control circuits send DC power to the plurality of MPSs. The sending includes a first voltage conversion. The DC power that was sent is transferred, by the plurality of MPSs, to the plurality of functional chips. The transferring is based on the plurality of TSVs.

A wafer 710 is shown. The wafer can include an inorganic, semiconductor wafer such as a wafer of silicon. The wafer can further be based on other inorganic materials such as glass. An example functional chip 720 is shown. The functional chip can include a chip based on a digital technology, an analog technology, a hybrid technology, and so on. A plurality of functional chips can be distributed across a surface such as a top surface of the wafer interposer. The functional chips can include substantially similar chips, a mix of similar chips and dissimilar chips, and the like. The functional chips can include chips of substantially similar sizes or substantially dissimilar sizes. The functional chips can include chips designed for one or more general purpose applications, for a specific application, and the like. In a usage example, the functional chips can be designed for a processing-intensive application such as training and running inferences on a neural network.

Power delivery to and heat removal from the functional chips within a wafer-scale integration system remain significantly challenging with respect to both design and implementation. In disclosed techniques, a modular approach is implemented for power delivery while accommodating various coefficients of thermal expansion of different materials in the technology stack. The heat is generated by the functional chips and other electronic elements during operation. The operation can include data processing such as processing for machine learning or other processing-intensive applications such as image processing, video processing, audio and speech processing, natural language processing, etc. In the disclosed techniques, power delivery modules and heat removal elements are positioned orthogonally to the plane of the functional chips. The power delivery can be accomplished using two stages. The first stage includes providing power from a main power source to components on a unified control board (UCB). The first power source can include a voltage between 48 and 54 volts. The UCB can include converters such as DC-to-DC converters on one side of the UCB, and modular connection points on the other side of the UCB. The modular connection points can include contacts and one or more rigid-flex strips. The modularity of the connections and the rigid flex strips are used to address differences in coefficients of expansion between elements such as the UCB and the wafer interposer. The second stage can include modular power substrates (MPSs). The MPSs are used to alter the DC voltage. The altering of the DC voltage is accomplished in multiple stages. In embodiments, the first voltage conversion can be based on a 4:1 voltage ratio. The second voltage conversion can be based on a 12:1 voltage ratio. The second voltage conversion can result in a voltage less than a threshold such as 1 volt.

The heat that is dissipated by the functional chips, the DC-to-DC power converters, and other elements cause functional chips, the wafer-scale silicon interposer, the modular power substrates, and the unified control boards to expand and contract due to increased and decreased temperature, respectively. The expansion and compression of the various elements pose mechanical challenges because the coefficients of expansion among the components can be different. Modular placement of the functional chips on a top side of the interposer, and the placement of the modular power substrates on the back side of the interposer, are configured to accommodate the differing coefficients of expansion of the power board and the interposer wafer. That is, some elements such as the wafer interposer and the UCB can expand by different amounts, thereby introducing stresses into the connections. This is especially true when a UCB is mounted directly to the WSSI. In this case, the connections, which can be micro-bumps or C4s, can easily crack due to differences in lateral movement between the components. The modular MPS design and rigid-flex strips can reduce the risk of potential mechanical damage or electrical interruption by enabling sufficient movement between elements across the UCB and WSSI. In some cases, the boards, such as the unified control boards, can be sized such that effects of the differences between coefficients of expansion can be minimized. In another technique, the coefficient of expansion of substrate, the interposer, and so on can be matched as closely as possible. In a usage example, the matching or near-matching can be accomplished by changing the material used for the interposer. The material used for the interposer can include an inorganic material such as silicon or glass as opposed to an organic material such as the materials routinely used for printed circuit boards.

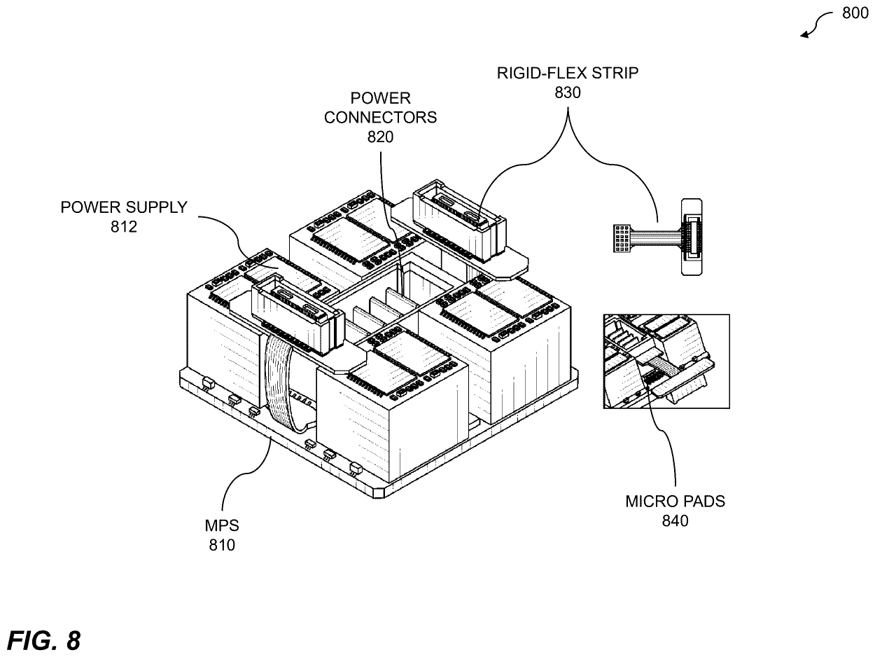

FIG. 8 is a diagram of a modular power substrate (MPS). Integrated circuits such as processor circuits require power in order to operate. When many circuits are obtained to achieve an objective such as a processing object, the power requirements for the many circuits becomes more stringent. The power requirements become more stringent because the aggregate power delivery to the chips can include tens, hundreds, or more amperes. Further, the power provided to the many circuits generates heat. The heat generated by the various elements of a system such as power supplies, functional chips, and so on causes the elements to expand. Since the elements comprise different materials, coefficients of expansion of the elements can differ.

To counter the potentially disastrous effects such as breakage resulting from differing coefficients of expansion, power supplies that can be used to power one or more functional chips can be arranged on one or more modular power substrates (MPSs). The MPSs can provide “flex” between other elements that expand and contract, minimizing potential material strain. The MPSs enable back side wafer-scale integration. A wafer-scale silicon interposer (WSSI) is accessed. A front side of the WSSI is bonded to a plurality of functional chips. The WSSI includes a plurality of through-silicon vias (TSVs). A plurality of modular power substrates (MPSs) is attached to a back side of the WSSI. Each MPS is coupled to one or more functional chips within the plurality of functional chips. The plurality of MPSs is mechanically connected to one or more control circuits. The one or more control circuits include a plurality of DC-to-DC power converters. The one or more control circuits can comprise one or more control boards.

The one or more control boards can comprise a unified control board (UCB). The one or more control circuits send DC power to the plurality of MPSs. The sending includes a first voltage conversion. The DC power that was sent is transferred, by the plurality of MPSs, to the plurality of functional chips. The transferring is based on the plurality of TSVs.

The diagram 800 illustrates a modular power substrate (MPS). Elements such as one or more power supplies, connectors, rigid-flix strips, etc. can be mounted to an MPS 810. The number of elements that can be attached to the MPS can be based on the size, shape, and so on of the MPS. A plurality of MPSs can be used to deliver power to a plurality of functional chips. The MPS can be based on a variety of substrate materials. In embodiments, one or more MPSs within the plurality of MPSs can include an organic substrate. An organic substrate can be based on organic materials such as organic materials used to manufacture printed circuit boards. The organic substrate materials can include paper cores impregnated with phenolic resin; woven or unwoven glass cloth impregnated with epoxy or cyanate ester among others; natural fibers; etc. In other embodiments, one or more MPSs within the plurality of MPSs can include an inorganic substrate. An inorganic substrate can be based on silicon, glass with a similar coefficient of expansion to the MPS, etc.

An MPS can include a form factor. A plurality of functional chips can be on a front side of a wafer-scale silicon interposer (WSSI). In embodiments, a plurality of MPSs is based on a form factor mirroring one or more corresponding functional chips, within the plurality of functional chips, on the front side of the WSSI. The plurality of MPSs is coupled to the plurality of functional chips. The MPSs can be mechanically connected to a unified control board (UCB) as well as attached to a back side of the WSSI. Thus, the MPSs can be located between the UCB and the WSSI. As described above, the WSSI and the UCB can have different coefficients of thermal expansion leading to different lateral movements. These lateral movements can be sufficient to crack connections and/or introduce warpage into components, which can lead to connection failures such as disconnected connectors, cracked C4s, damage due to physical strain, etc. The modularity of the MPSs can provide a flexible power delivery system to the functional chips which can accommodate different movements of the WSSI and UCB due to thermal expansion. For example, an MPS at one side of the WSSI can be decoupled from an MPS on the other side of the WSSI, thus accommodating various movements across the WSSI and UCB.

A power supply 812 can be coupled to the MPS. In the figure, three additional power supplies are shown attached to the MPS. The number of power supplies attached to the MPS can be based on the dimensions of the MPS, the dimensions of the power supplies, a voltage or current required by the functional chips, coefficients of expansion, heat dissipation, etc. The MPS can include power connectors 820. The power connectors can fit with a high voltage socket from the UCB. The power connectors can include one or more of positive terminals, negative terminals, common terminals, and so on. The high voltage socket can accommodate lateral movement due to thermal expansion. The MPS can include one or more rigid-flex strips 830. The one or more rigid-flex strips can be used to connect an MPS to the UCB. The connection can include control signals, power delivery, and so on. The rigid-flex strips can provide further protection from differing rates of thermal expansion between the WSSI and the UCB, through the use of a flexible connector. The rigid-flex strips can be attached to the MPS by a plurality of micro pads 840. The MPSs can include micro pads, micro-bumps, C4s, a ball grid array (BGA), etc. on the back side (not shown), which can be used to connect the MPS to the WSSI.

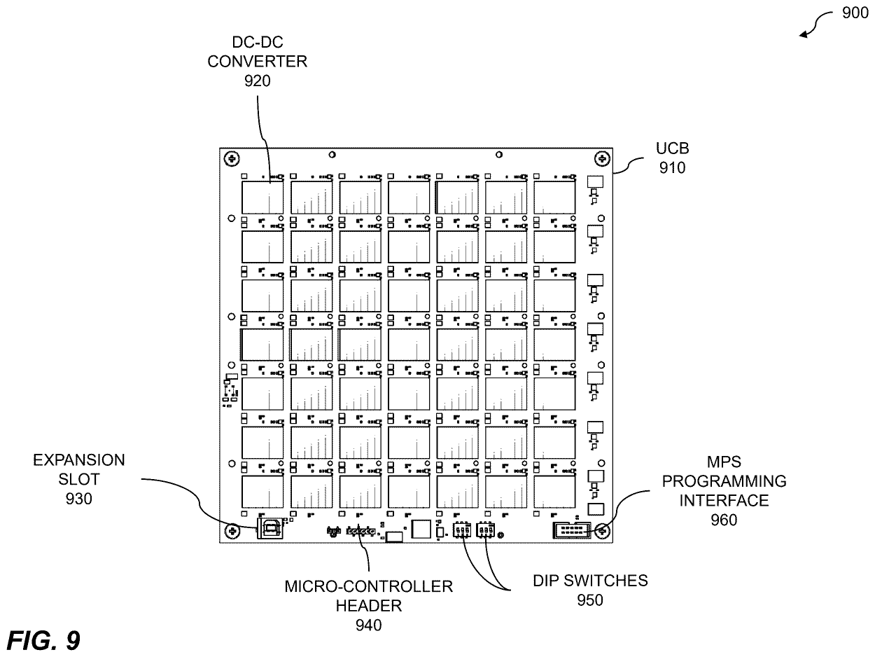

FIG. 9 is a diagram of a front side of a unified control board (UCB). One or more modular power substrates such as the modular power substrates described previously can be mechanically connected to one or more control circuits. The control circuits can be used to provide power to power supplies, to provide DC power to DC-to-DC converters, to obtain DC power from the DC-to-DC converters, to control multiple instances of output current drivers, and so on. A control circuit can include a control board. In embodiments, one or more control circuits can include one or more control boards. The circuit boards can include organic circuit boards or inorganic circuit boards. The control boards can be used to control the modular power substrates, the DC-to-DC converters, and the like. In embodiments, the one or more control boards can include a unified control board (UCB). The UCB enables back side wafer-scale integration with power delivery. A wafer-scale silicon interposer (WSSI) is accessed. A front side of the WSSI is bonded to a plurality of functional chips. The WSSI includes a plurality of through-silicon vias (TSVs). A plurality of modular power substrates (MPSs) is attached to a back side of the WSSI. Each MPS is coupled to one or more functional chips within the plurality of functional chips. The plurality of MPSs is mechanically connected to one or more control circuits. The one or more control circuits include a plurality of DC-to-DC power converters. The one or more control circuits send DC power to the plurality of MPSs. The sending includes a first voltage conversion. The DC power that was sent is transferred, by the plurality of MPSs, to the plurality of functional chips. The transferring is based on the plurality of TSVs.

A front side of a unified control board (UCB) is shown 900. The UCB 910 can include elements such as one or more of power elements, interfaces such as programming interfaces, switches, connectors, headers, and so on. One or more DC-to-DC converters 920 can be coupled to the UCB. The one or more DC-to-DC converters can be matched to modular power substrates (MPSs). Further embodiments include matching each DC-to-DC power converter within the plurality of DC-to-DC power converters included on the UCB to one or more respective MPSs in the plurality of MPSs. The MPSs can be arranged on the UCB based on a grid, an array, and so on. In a usage example, MPSs can be arranged in a 7×7 array. The UCB can include an expansion slot 930. The expansion slot can include a connector such as a USB™ connector. In a usage example, the expansion slot can be used to expand the UCB using a micro-controller programming technique. The UCB can include a micro-controller header 940. The micro-controller header can be used to provide an interface to a micro-controller, a micro-sequencer, and the like. The UCB can include one or more dual in-line package (DIP) switches 950. The DIP switches can be used to select one out of a plurality of MPSs on the UCB, a level of power associated with the MPSs, and so on. In a usage example based on the 7×7 array of MPSs, the DIP switches can be used to select one of the 7×7 MPSs for switching phase-controllers. The UCB can include an MPS programming interface 960. The programming interface can be based on a header such as a shrouded header. The header can be configured to couple to an interface element such as a programming dongle.

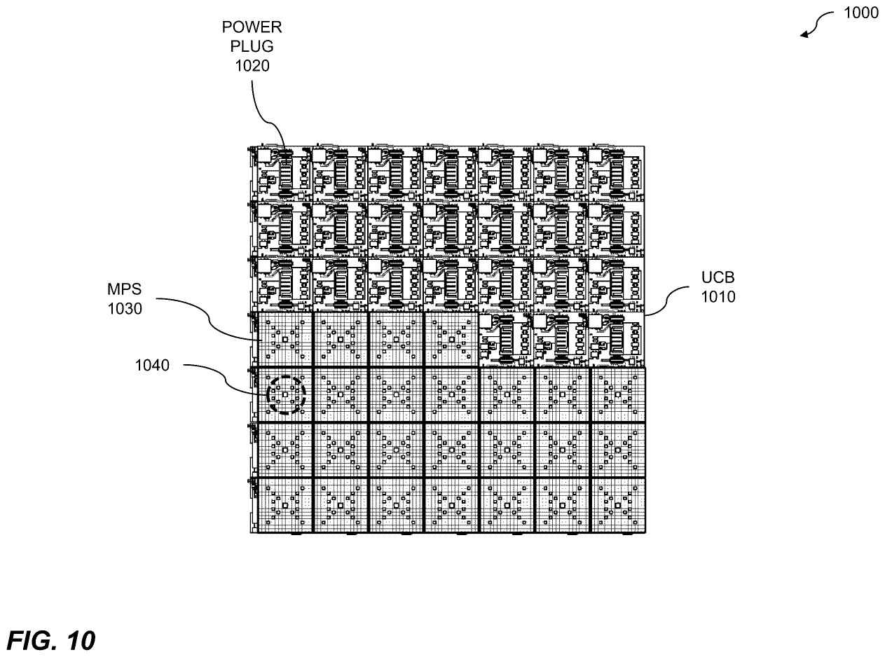

FIG. 10 is a diagram of a back side of a unified control board. The use of the front side of the unified control board (UCB) for placement of DC-to-DC converters, slots, headers, DIP switches, interfaces, and so on was discussed previously. The back side of the UCB is also used for connection of various elements. The various elements can include one or more modular power substrates (MPS). The MPSs described above can be connected to the back side of the UCB using plugs, connectors, and so on. The plugs and/or connectors can enable power connections; command, control, and configuration information; and so on. The connection of the MPSs to the UCB enables back side wafer-scale integration with modular power delivery. A wafer-scale silicon interposer (WSSI) is accessed. A front side of the WSSI is bonded to a plurality of functional chips. The WSSI includes a plurality of through-silicon vias (TSVs). A plurality of modular power substrates (MPSs) is attached to a back side of the WSSI. Each MPS is coupled to one or more functional chips within the plurality of functional chips. The plurality of MPSs is mechanically connected to one or more control circuits. The one or more control circuits include a plurality of DC-to-DC power converters. The one or more control circuits send DC power to the plurality of MPSs. The sending includes a first voltage conversion. The DC power that was sent is transferred, by the plurality of MPSs, to the plurality of functional chips. The transferring is based on the plurality of TSVs.

The figure shows connections of modular power substrates to a unified control board (UCB) 1000. The UCB 1010 can include a wafer-scale silicon interposer (WSSI). A UCB can be configured such that a plurality of MPSs can be connected to the UCB in a pattern such as an array pattern. In a usage example, the array of connected MPSs can include a 7×7 array.

The connecting of the MPSs can be based on a form factor. In embodiments, the plurality of MPSs can be based on a form factor mirroring one or more corresponding functional chips, within the plurality of functional chips, on the front side of the WSSI. Discussed below, an MPS on the back side of the UCB can be matched to a DC-to-DC converter on the front side of the UCB.

The UCB can be populated with a plurality of power plugs 1020. A power plug can be configured to couple to an MPS 1030. The plurality of power plugs can be arranged on the UCB in a pattern such as an array. As stated in previous usage examples, the plurality of power plugs can be arranged in a 7×7 array. One or more MPSs are connected to the UCB using one or more power plugs. The connections can include mechanical connections that can be connected for installation or disconnected for removal or replacement. The MPSs can include micro-bumps, C4s, a ball grid array (BGA), etc. on the back side as shown at 1040. These elements can be used to connect the MPS to the WSSI.

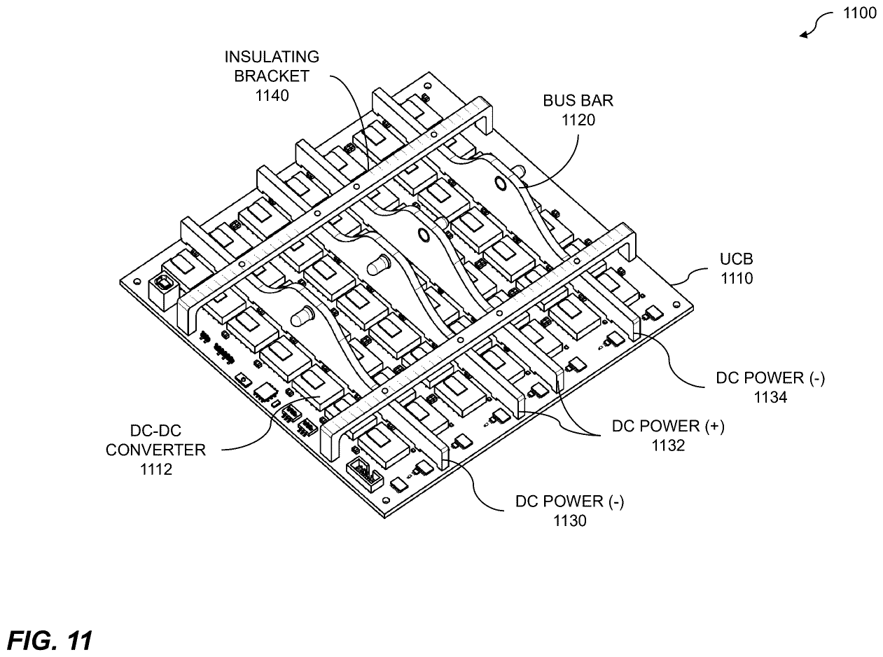

FIG. 11 is a diagram of a bus bar coupled to a UCB 1100. Power must be provided to functional chips in order for the chips to operate. Since the functional chips can include powerful processors including processors for applications such as deep learning, a substantial amount of power must be provided to the chips. The power can be provided using a high-current handling technique. The high-current technique can be based on the use of one or more bus bars. Providing power via one or more bus bars enables back side wafer-scale integration with modular power delivery. A wafer-scale silicon interposer (WSSI) is accessed. A front side of the WSSI is bonded to a plurality of functional chips. The WSSI includes a plurality of through-silicon vias (TSVs). A plurality of modular power substrates (MPSs) is attached to a back side of the WSSI. Each MPS is coupled to one or more functional chips within the plurality of functional chips. The plurality of MPSs is mechanically connected to one or more control circuits. The one or more control circuits include a plurality of DC-to-DC power converters. The one or more control circuits send DC power to the plurality of MPSs. The sending includes a first voltage conversion. The DC power that was sent is transferred, by the plurality of MPSs, to the plurality of functional chips. The transferring is based on the plurality of TSVs.

Power can be provided to a unified control board (UCB) 1110 using one or more bus bars. The bus bars can be used to power one or more elements on the UCB, where the elements can include DC-to-DC converters 1112. The one or more bus bars can be formed from a metal such as copper. The metal used in the bus bar can be chosen for current handling capabilities, compatibility with other conductors on the UCB, and so on. An example bus bar 1120 is shown. The bus bars can typically include one or more positive bus bars and one or more negative bus bars. The bus bars can be arranged on the UCB such that each element on the UCB can be adjacent to a positive bus bar and to a negative bus bar. In the figure, bus bars associated with DC power are shown. The bus bars can include a negative DC power bar 1130, two positive DC power bars 1132, and a second negative DC power bar 1134. In a usage example, the UCB is configured in a 7×7 array. The positive DC power bus bars and the negative DC power bus bars are positioned such that positive DC power and negative DC power can be made available to each DC-to-DC converter within the 7×7 array. One or more insulating brackets 1140 can be used to support the UCB and the bus bars. The insulating brackets can also serve as spacers between the UCB and other elements associated with back side wafer-scale integration.

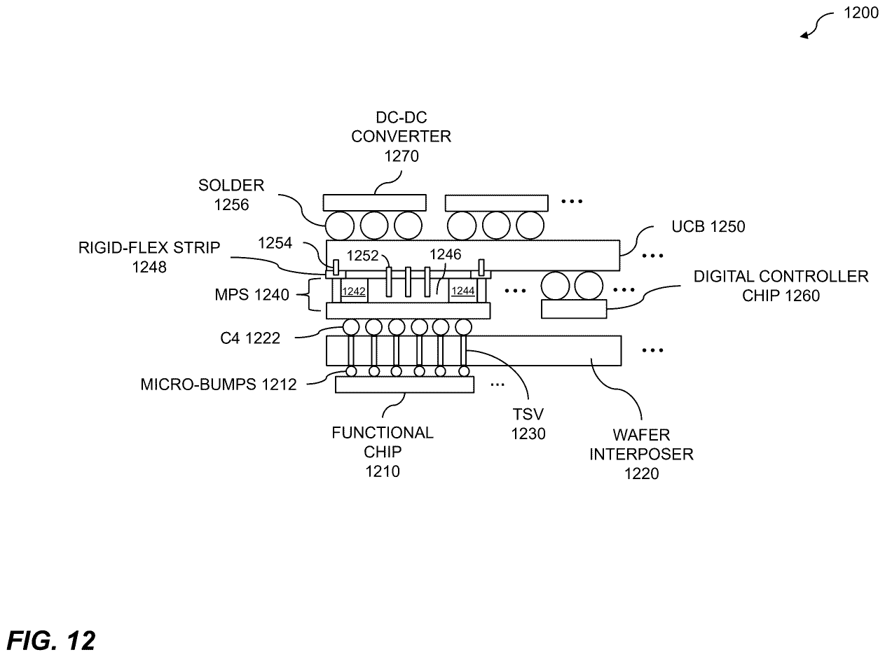

FIG. 12 is a cross-section of an apparatus for back side wafer-scale integration with modular power delivery. Discussed throughout, wafer-scale integration (WSI) can be achieved through the use of a wafer-scale silicon interposer (WSSI). The WSSI can be used to mount various elements and to provide interconnections among the mounted elements. The silicon interposer can include other inorganic materials such as glass, where the inorganic material can be chosen to match coefficients of expansion of elements that can be mounted to the WSSI with the coefficient of expansion of the interposer. Choosing a material with an expansion coefficient similar to the coefficients of expansion of elements mounted to the WSSI can significantly reduce physical damage to the WSSI or the attached elements. The physical damage can result from strains imposed on the elements and on the WSSI, where the strains are attributable to different coefficients of expansion. The interposer such as the silicon interposer can further assist with removal of heat from the elements as the elements such as functional chips, DC-to-DC converters, controller chips, and so on, are operating. FIG. 12 can include an apparatus for power delivery comprising: a wafer-scale silicon interposer (WSSI), wherein a front side of the WSSI is bonded to a plurality of functional chips, and wherein the WSSI includes a plurality of through-silicon vias (TSVs); a plurality of modular power substrates (MPSs), wherein the plurality of MPSs is based on a form factor mirroring one or more corresponding functional chips, within the plurality of functional chips, on the front side of the WSSI, and wherein the plurality of MPSs is attached to a back side of the WSSI; and one or more control circuits, wherein the one or more control circuits includes a plurality of DC-to-DC power converters, and wherein each DC-to-DC power converter in the plurality of DC-to-DC power converters includes a mechanical connection to a respective MPS in the plurality of MPSs.

An apparatus for power delivery accomplishes back side wafer-scale integration with modular power delivery. The apparatus 1200 can include a functional chip 1210. The functional chip can include a processor chip, multi-core processor chip, system-on-a-chip, memory chip, application-specific integrated circuit (ASIC), artificial intelligence accelerator, and so on. The functional chip can include an integrated circuit designed for a flip-chip application. A chip design for a flip-chip application can include a chip for which connections to the chip are accomplished at the top layer of the chip. The connections can include positive and negative DC power connections, data connections, control connections, and so on. The various chip connections can include pads on the top layer of the chip. The functional chip can include a chip that can accomplish a processing function such as a functional chip that has been designed for deep learning. Various techniques can be used to make connections to the top of a functional chip. In a usage example, a technique based on micro-bumps 1212 can be used. A micro-bump can be associated with each connection point or pad on the chip. The micro-bumps can comprise a dense array of connection points or pads. The micro-bumps can include a material appropriate for mounting the chip to a substrate, a board, an interposer, and so on. The micro-bumps can include solder micro-bumps. The micro-bumps can be arranged in a ball grid array (BGA) or some other geometry.

The apparatus 1200 includes a wafer interposer 1220. The wafer interposer can include an interposer that enables wafer-scale integration (WSI). The wafer interposer can include organic materials or inorganic materials. In embodiments, the interposer can include a wafer-scale silicon interposer (WSSI). Other inorganic materials can be used. In a usage example, the wafer interposer can include a glass interposer. The glass used for an interposer can include a glass chosen for a coefficient of expansion which can be substantially similar to a coefficient of expansion of other elements such as one or more functional chips. The micro-bumps discussed above can be used to mount the one or more functional chips to the wafer interposer. Communications between the functional chips can be accomplished within metal layers of the silicon interposer, improving latency, signal integrity, parasitics, and/or bandwidth as many more wires can be established within the silicon wafer than would have been possible with a typical packaging interface. Thus, the WSSI can enable extremely high bandwidth buses and control signals between chips mounted to the WSSI. In embodiments, the WSSI includes one or more optical waveguides. The optical waveguides can enable chip-to-chip communications via light. The optical waveguides can comprise the buses and control signals between chips. The wafer interposer can also be used to attach additional boards, modules, components and so on. The further attachments can be located on the opposite side of the wafer interposer from the mounted functional chips. The further wafer interposer attaching can be based on one or more controlled collapse chip connection bumps (C4s) 1222. The wafer interposer can provide connections between the micro-bumps on one side of the wafer interposer and the other side of the wafer interposer. In embodiments, the WSSI includes a plurality of through-silicon vias (TSVs) 1230. The TSVs can provide a connection between the micro-bumps and the C4s. These connections can be used to deliver power to the functional chips through the back side of the WSSI, as is described below.

The apparatus 1200 includes a plurality of modular power substrates (MPSs) 1240. An MPS can be based on a form factor. The form factor of the MPS can be associated with or dependent on components mounted to the wafer interposer. In embodiments, the plurality of MPSs is based on a form factor mirroring one or more corresponding functional chips, within the plurality of functional chips, on the front side of the WSSI. The form factor of the MPS can have a 1:1 relationship to the one or more corresponding functional chips or can include other shape factors. The MPSs can be based on a variety of materials. In embodiments, one or more MPSs within the plurality of MPSs comprise an inorganic substrate. An inorganic substrate can include a silicon substrate, a glass substrate, and so on. In other embodiments, one or more MPSs within the plurality of MPSs comprise an organic substrate. The organic substrates can include substrates such as printed circuit boards. Recall that the functional chips are mounted to the front or top side of the WSSI. In embodiments, the plurality of MPSs is attached to a back side of the WSSI. Connections between the wafer interposer and the MPS can be accomplished using the C4s described above.

The MPS can include a plurality of step-down power modules and/or DC-to-DC converters such as those shown at 1242 and 1244. As shown in a previous diagram, the DC-to-DC converters on an MPS can be placed across the MPS. The DC-to-DC converters on the MPSs can accomplish altering of a DC voltage. The altering the DC voltage can result in a second DC voltage. Embodiments can include altering, by the plurality of MPSs, the DC power that was sent, wherein the altering is based on a second voltage conversion. The second voltage conversion can include a second DC-to-DC voltage conversion. In embodiments, the second voltage conversion results in a voltage less than a threshold. The threshold can include a voltage appropriate to a voltage required by a functional chip. In embodiments, the threshold can include 1 volt.

An MPS can include a connector 1246. The connector can be used to mechanically connect the MPS to a unified control board (UCB). The connector can include a socket on the UCB. The mechanical connection can include one or more pins 1252 which can be inserted into the socket. In embodiments, the mechanical connection is based on a high voltage socket wherein the high voltage socket transfers power from the UCB to the plurality of MPSs. The high voltage socket can be used to provide a first DC voltage that can be converted to a second DC voltage by one or more DC-to-DC converters. In embodiments, the mechanical connection accommodates a maximum lateral displacement of the UCB due to thermal expansion during operation. The lateral displacement can result from thermal expansion of the WSSI, the UCB, and/or the MPS during operation. In addition to the power connector, the MPS can include a rigid-flex strip 1248. The rigid-flex strip can provide a mechanical connection between the MPS and a UCB. The plurality of rigid-flex strips can provide control signals, data, and so on. In embodiments, the mechanical connection can include a plurality of rigid-flex strips. In further embodiments, the plurality of rigid-flex strips includes one or more power control signals from the digital controller chip to the plurality of MPSs. The plurality of rigid-flex strips can include one or more signals such as one or more power control signals. In embodiments, the plurality of rigid-flex strips carries at least a portion of DC power from the plurality of MPSs to the plurality of functional chips. The rigid-flex strips can include a socket into which one or more plugs, pins, etc., such as 1254, can be inserted to couple the rigid-flex strip to the UCB.

The apparatus 1200 can include one or more control circuits, wherein the one or more control circuits include a plurality of DC-to-DC power converters, and wherein each DC-to-DC power converter in the plurality of DC-to-DC power converters includes a mechanical connection to a respective MPS in the plurality of MPSs. In embodiments, the one or more control circuits comprise one or more control boards. In embodiments, the one or more control boards comprise a unified control board (UCB). The mechanical connection between each DC-to-DC converter and a respective MPS enables power transfer, control, and so on. The mechanical connections between the plurality of DC-to-DC converters and the plurality MPSs can remain reliable when the DC-to-DC converters and the MPSs are operating. In embodiments, the mechanical connection can accommodate a maximum lateral displacement of the UCB due to thermal expansion during operation. The handling maximum lateral displacement is critical to maintaining reliable mechanical connections between and among components, the WSSI, one or more UCBs, one or more MPSs, and so on. The control circuits can be mounted singly, in sets, in entirety, and so on; on a board, a substrate, a wafer, and the like. In embodiments, the one or more control circuits comprise one or more control boards.

Discussed previously and throughout, boards such as the one or more control boards can include organic control boards and inorganic control boards.

In embodiments, the one or more control boards can include a unified control board (UCB) 1250. As described above, the UCB can include a mechanical connector such as a plug, a socket, a terminal, and so on for connecting the one or more MPSs. In embodiments, the mechanical connection can be based on a high voltage socket, wherein the high voltage socket transfers power from the UCB to the plurality of MPSs. The mechanical connection between plug and socket can enable transfer of DC power between a UCB and an MPS. The plug and socket configuration can also accommodate lateral displacement due to thermal expansion.

In embodiments, the UCB includes a digital controller chip 1260, wherein the digital controller chip controls power delivery to the plurality of functional chips. The controlling power delivery can include enabling or disabling power transfer, controlling an input voltage to and an output voltage from a DC-to-DC converter, and the like. The controlling can apply to a single DC-to-DC converter or a plurality of DC-to-DC converters. Recall that the MPS can include a plurality of rigid-flex strips that can accommodate lateral displacement of the UCB due to thermal expansion during operation. The rigid-flex strips can accomplish other functions. In embodiments, the plurality of rigid-flex strips can include one or more power control signals from the digital controller chip to the plurality of MPSs. The control signals can enable and disable elements such as controller chips and DC-to-DC converters, can provide instructions to controller chips, etc. In further embodiments, the plurality of rigid-flex strips carries at least a portion of DC power from the plurality of MPSs to the plurality of functional chips. In a usage example, the rigid-flex strips can carry output power from power supplies. Since the UCB can be providing power for a plurality of DC-to-DC converters, and ultimately to functional chips, the UCB can draw a substantial, high current. Further embodiments include one or more high current bus bars, wherein the one or more high current bus bars are coupled to the one or more control circuits. The one or more high current bus bars can include one or more of a positive bus bar and a negative bus bar. Positive bus bars and negative bus bars, when present, can provide power to the one or more control circuits.

The apparatus 1200 can include one or more solder bumps 1256. The solder bumps can be positioned on a side of the UCB opposite to the side of the UCB that includes the mechanical connections to the MPSs. The solder bumps can be placed on contacts or pads. The solder bumps can be arranged in array pattern such as a regular array pattern. The solder bumps can be placed on fewer pads than a regular array. The apparatus 1200 can include a DC-to-DC converter 1270. The DC-to-DC converters can convert a first DC voltage to a second DC voltage. The DC-to-DC converters can be controlled by a control chip associated with the UCB. The DC-to-DC converters can be coupled to the UCB using the solder bumps. Further embodiments can include matching each DC-to-DC power converter within the plurality of DC-to-DC power converters included on the UCB to one or more respective MPSs in the plurality of MPSs. DC power from a DC-to-DC converter can be sent to a MPS via interconnect on the UCB. DC Power can be fed to the DC-to-DC converters.

Embodiments include feeding the DC power, by one or more high current bus bars, to the UCB. The high current bus bars can include one or more of a positive bus bar and a negative bus bar. In embodiments, a voltage range of the DC power that was fed comprises a first voltage range. The first voltage range can include a voltage range that can be converted by the DC-to-DC converters. In embodiments, the first voltage range is 48 volts to 54 volts, inclusive. The DC-to-DC converters can convert a voltage based on a ratio. In embodiments, the first voltage conversion is based on a 4:1 voltage ratio. In embodiments, the first voltage conversion results in a second voltage range. In embodiments, the sending can include altering, by the plurality of MPSs, the DC power that was sent, wherein the altering is based on a second voltage conversion. The second voltage can include a range, where the range of the second voltage is based on the conversion ratio. In embodiments, the second voltage range is 12 volts to 13.5 volts, inclusive. A second voltage conversion can be performed. In embodiments, the second voltage conversion results in a voltage less than a threshold. A threshold can be a set threshold, where the threshold is set by the controller. In embodiments, the threshold is 1 volt. Other threshold voltages can also be set. For example, the second voltage conversion can result in a voltage of 0.85 volts to drive core logic elements. Functional chips can require additional voltages for I/O as well as for powering logical elements. Thus, the altering can produce an additional voltage output. The additional voltage output can be above or below the voltage less than a threshold. For example, the additional voltage output can be 1.2 volts to supply a voltage for I/O circuits.

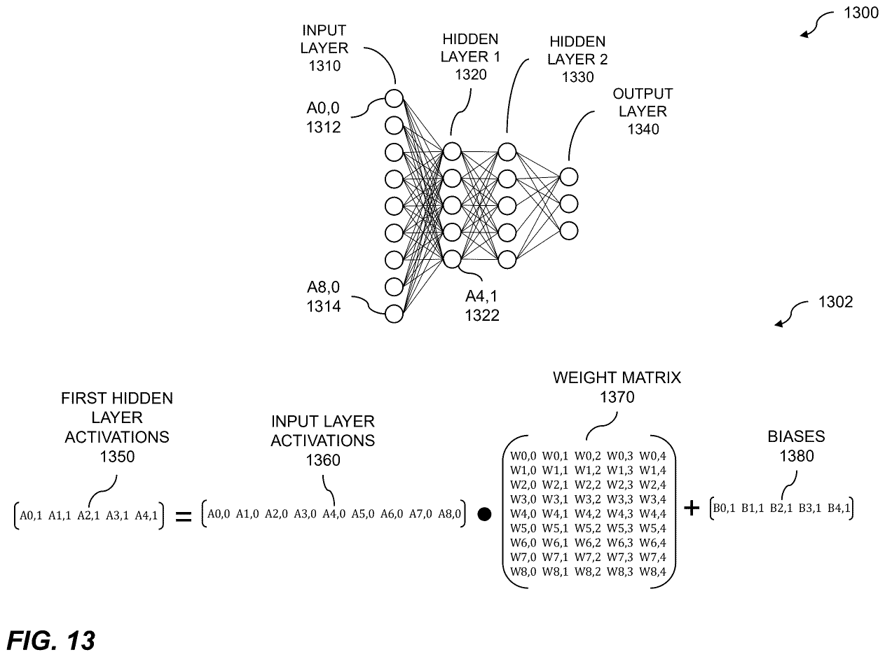

FIG. 13 is an illustration of a neural network. The neural network (NN) can include a convolutional neural network (CNN). A convolutional neural network can be a type of deep learning system that can learn from data such as training data fed into the system. The training data can be provided with “known good” or expected inferences and results. CNNs can be extensively used for image and video recognition, image classification, image segmentation, natural language processing (NLP), and so on. A CNN can use a few (such as tens), or many (such as hundreds, thousands, etc.) of layers of processing units called neurons. The neurons can enable calculations which can determine a weighted sum of inputs from previous neurons. The neurons can include a bias which can determine or alter the impact of a neuron on a future neuron. The neuron can include an activation function such as a sigmoid function, a rectified linear unit (ReLU) normalization function, and so on to ensure that the value calculated by the neuron remains between 0 and 1. The value stored in the neuron can be called an “activation”. The neuron can process any type of data including any floating-point format such as single floating-point, double floating-point, brain floating-point 16 (BF16), BF8, and so on. The neurons can be arranged into layers. The output of a neuron in one layer can be used to feed one or more neurons in another layer. One or more layers can comprise fully connected layers where a neuron in a first layer is connected to every neuron in a previous layer. The various layers and connections between layers can form the basis of an inference operation by the neural network.

The illustration 1300 shows an example CNN comprising groups of neurons arranged by layers within a network architecture. The input data for a neuron can come from an original data source, such as a video image, or from a previous input layer of neurons. The output value from each neuron can be used to feed another layer of neurons or can be part of a final output layer. In the illustration 1300, the first layer at the left of the figure can be called the input layer 1310. Each neuron or processing unit in this layer can receive data directly from a source such as a still camera, video camera, passive infrared (PIR) camera, and so on. Neurons can be numbered for identification. For example, 1312 shows neuron which contains an activation for the first layer at a first neuron. Thus, this neuron can be labelled A0,0. In a similar manner, 1314 shows neuron A8,0, which can refer to the ninth neuron in layer 0. This can indicate that there are 9 neurons/activations in the first layer (e.g., “layer 0”) of the neural network. In practice, any layer can contain any number of neurons. The number of neurons in a given layer can be heuristically determined. Large CNNs can have thousands or millions of neurons at the input layer.

The numeric values calculated by each neuron (called activations) in the input layer can become the input for the next layer of neurons. The next layer of neurons can be a hidden layer. Any number of hidden layers can be included in the neural network. In the illustration 1300, the first hidden layer is hidden layer 1 1320 and includes 5 neurons. A second hidden layer 1330 is included which also has 5 neurons. A final layer, an output layer 1340 is shown which includes 3 neurons. The output layer can comprise the final inference from the neural network. For example, if the neural network depicted in 1300 comprises a system for determining whether a traffic light was red, yellow, or green, the top activation function/neuron in the output layer could be for red, the middle could represent yellow, and the bottom green. The final value found in each activation within the output layer can comprise a probability. For example, the final output layer could comprise values (from top to bottom) such as 0.01, 0.2, and 0.99. The strength of the network prediction can grow the closer the output value is to 1. Thus, the neural network in this case can indicate a high probability that the light is green.

In practice any number of neurons can be included in any number of hidden layers. A hidden layer within the CNN can include a truncation layer, a bottleneck layer, and so on. The illustration 1300 shows that every calculated value from the input layer is connected to every neuron in the first hidden layer. The first hidden layer is described as a fully connected layer. Each connection can be associated with a weight and a bias. Weights and biases can determine how much the value in the current neuron should affect other neurons in the next layer. Thus, the connection between A0,0 1312 and A4,1 1322 can include a first weight while the connection between A8,0 1314 and A4,1 can include a different weight. A unique bias can be associated with A4,1. The weights can be labelled to make it clear which nodes are coupled between a previous layer and a current layer. For example, for the first hidden layer, W0,0 can couple neuron 0 from the input (previous) layer to neuron 0 in hidden layer 1 (the current layer).

In a similar way, the value for each neuron in the first hidden layer can be determined by a large matrix multiply function as shown in illustration 1302. Each activation function in the first hidden layer can be represented by a 1-dimensional vector such as shown at 1350. The activations from the input layer can be shown in another 1-dimensional matrix such as 1360. A 9×5 matrix can be created which includes all weights between the first input layer and the first hidden layer as shown at 1370. In practice the weights can comprise any number of rows and columns according to the size (e.g., number of neurons) of the layers. Finally, the biases associated with each connection from the input layer to the first hidden layer can be represented in a 1-dimensional matrix such as 1380. For example, in the illustration 1300, the value of A4,1 1322 can be the sum of all the weighted (W) inputs from the previous layer, with a final bias added as shown in the following equation: A4,1=[(A0,0*W0,4)+(A1,0*W1,4)+ . . . +(A8,0*W8,4)+B4,1]. As stated previously, the activation A4,1 can include non-linear transformation such as a sigmoid, ReLU, Tanh, and Softmax. The non-linear transformation function can ensure that the value of the activation remains between 0 and 1 and does not “saturate” with a value or 1 or a value of 0.

Each transition to a different layer within the neural network can require a different matrix multiplication function. Thus, a neural network with many layers can heavily tax a processor core. As the number of neurons/activations within the layers grows, the matrix multiplication function grows increasingly complex. For example, the total number of weights and biases in a neural network can be called the number of parameters in the system. In the case of illustration 1300, relatively few parameters have been included. In the first layer, each of the nine neurons is connected to 5 neurons, with each connection including a weight. A separate bias can be included for each of the 5 neurons. Thus, in an example configuration, the first layer can include 9×5+5=50 parameters. The second layer includes 5 neurons connected to another 5 neurons at the next layer, each connecting including a weight. Again, a bias can be included for each neuron. Thus, the parameter count for the second layer as shown is 5×5+5=30. The third layer comprises 5 neurons with each neuron connected to 3 neurons in the output layer, where each connection also includes a weight. A bias can be included for each of the three neurons. Thus, the number of parameters is 5×3+3=18. Thus, the number of total parameters in the system can be 50+30+18=98.

Consider a large neural network used for modern large language models. As these networks can comprise billions or trillions of parameters, the matrix multiply function can be exceedingly large. To lessen processing bottlenecks, the matrix multiply functions required, which can include matrices with hundreds, thousands, or even millions of rows and columns, can be broken up based on submatrices and distributed across many special purpose processors. This technique can decrease the processing time required to perform each matrix multiply, however, this approach can drive bandwidth requirements between many processors and many memory chips as the single large matrix multiply can be split, sent to many processors for execution, collected at a central processor, and then the result must be combined. In large neural networks, this can occur for every inference, driving large memory bandwidth requirements. For example, if 1 billion parameters are used in a neural network, each saved in a single precision floating point format (32-bits), the resulting model could require tens of megabytes (MB) of memory simply to store the parameters of the network. A neural network with 1 trillion parameters could require tens of gigabytes (GB) of memory. As discussed below, training the neural network can drive the need for additional bandwidth as each processor must keep a copy of the previous activations, weights and biases that are required to perform a matrix multiply. In addition, the training data must be sent, which can also be quite large. In sum, while neural networks have driven processor improvements, especially in matrix multiply efficiency, the bandwidth needed to keep each processor occupied in a large neural network remains a significant challenge. This can be especially true for some neural networks such as transformers. In these cases, bandwidth requirements of running inferences can place a larger demand on the system than even training (as described below).

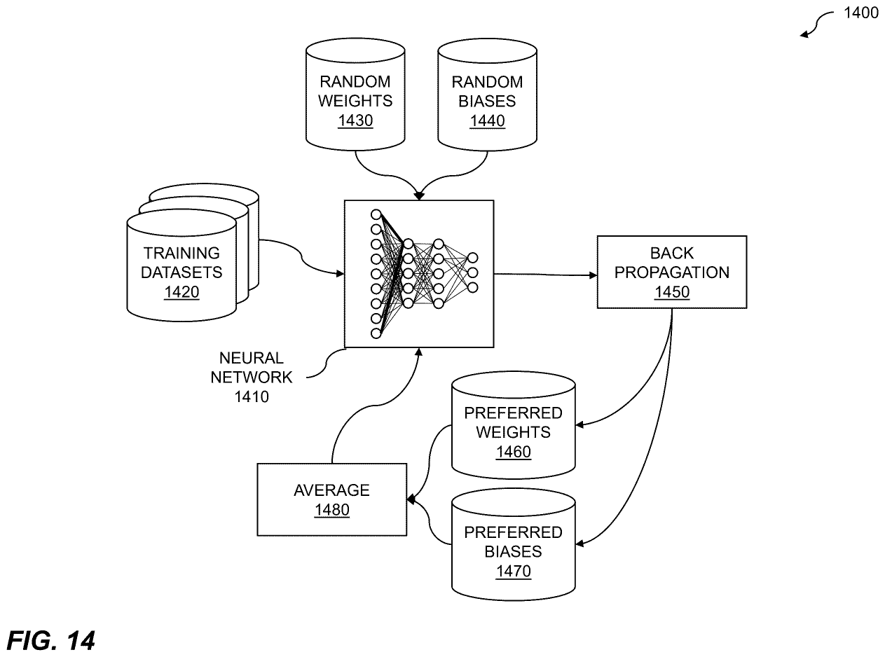

FIG. 14 is an example of training a neural network. A neural network 1410, as previously described in FIG. 13, is shown in example 1400. The neural network can comprise any number of neurons/activations. Training datasets 1420 can be provided to the neural network to train the neural network. The training datasets can be based on the type of inference required from the neural network. For example, if it is desired for the network to identify a type of animal, then the training set can include many different types of animals in many different settings and environments. In practice, a large amount of data is required to train a network to properly perform an inference. For example, in video processing/recognition, a rule of thumb can be 10 training images per parameter. Thus, a small neural network with 1,000 parameters could have 10,000 images or more for training. If these images are large, the memory requirement to store them can also be large. For example, 10,000 8-bit greyscale images in a resolution of 720×720 pixels could require: (8-bits/pixel)×(518,400 pixels)×(10,000 images)=40.5 GB. The memory requirement would be higher for color images or higher resolution images. To train a neural network, each of these images can be sent to the input layer of the neural network for training, requiring wide and fast memory connections to the processors performing the training.

The neural network can begin with a random set of weights 1430 and biases 1440. In some embodiments, a previous set of weights and biases may be used or have been obtained prior to training and used in place of purely random values. The training process can alter those weights and biases such that an accurate interference can be performed with inputs that the neural network has not previously seen. To train the network, a first image from the first training dataset can be sent to an input layer, as described in the previous figure. Each layer of the neural network can then calculate values based on a weighted sum of each connected neuron in the previous layer. This calculation continues until all neurons in all layers have generated an input. The final values can be captured at the output layer of the neural network. The training can comprise a supervised training. In supervised training, a desired output for each neuron in the output layer can be predetermined along with each training image. The predetermined desired output can be a label. A cost function can be created for each training image, which can be obtained by adding the squares of the differences between the result of each neuron in the output layer and the desired result (which can be found in the label of the training data) of that neuron.

Training can reduce the cost function associated with every training image by determining a gradient of the cost function for each image. This can be computed by back propagation 1450. The back propagation process can determine, for each neuron in the network, what changes should be made to its associated weight and bias to reduce the cost function most effectively. Since a neuron in a layer N is affected by the previous layer N-1, the neurons in N-1 must also be adjusted. Thus, back-propagation can be an iterative algorithm starting from an output layer of the neural network and ending at the input layer. To train the neural network, each image can be processed forward through the neural network and then backpropagated through the network to determine changes necessary for a more accurate inference in the future. This process can be repeated for each image in the training set. Because of the large amount of data required to keep all images in memory, the training data can be randomly divided into datasets which can also be “mini batches”. Training the network can take place on one mini batch at a time to lower bandwidth and compute requirements. For example, the neural network can perform forward processing and back-propagation on the first training image within the first mini batch, resulting in a first set of preferred weights 1460 and biases 1470. The preferred weights and biases can reflect a desired value for the weight and bias at every neuron to more accurately predict an output based on the first training image within the first mini batch. The neural network can then perform the same function on a second image, resulting in a second set of preferred weights and biases. This process can be repeated for each image in the mini batch. Once each image is processed, and an associated set of preferred weights and biases is computed, each preferred weight and bias for each node can be averaged 1480 to determine the final adjustment that will be made to the actual weights and biases in the network due to the mini batch of images. Once the neural network is updated, another mini batch of training images can be used to further train the network in the same way.

Consider a large neural network with billions of parameters and large matrices that must be calculated to determine each activation. Also consider the large amount of training image data that must be sent to the network and the amount of data that must be maintained during training (including the intermediate weights and biases for each node resulting from each training pass of each image in a mini batch prior to averaging). Finally, consider that a large neural network can be distributed across many functional processors, all with a need to access a relevant portion of the data described above. The bandwidth requirements for training such a neural network are extremely high. New methods and technologies can be required to feed such a distributed network.

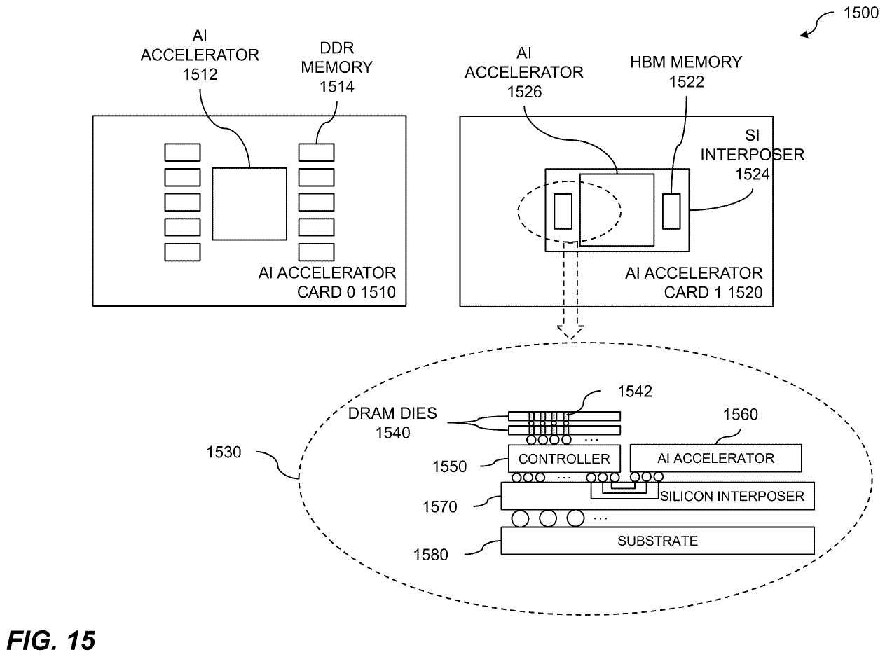

FIG. 15 is an example of enhancing memory bandwidth. As discussed above, modern large neural networks can include billions or even trillions of parameters, requiring many gigabytes to simply store the model. Training these large networks can require much more memory as thousands, hundreds of thousands, millions, or more samples of images, videos, text, papers, sentences, and so on must be presented to the neural network and then backpropagated through the network to determine adjustments for each of the numerous weights and biases comprising the network. Gradients, intermediate values for weights and biases, and so on must also be stored, further pressuring memory bandwidth. Diving the processing requirements for training and/or inference by the neural network can be straightforward. For example, a matrix multiply can be divided into multiple smaller matrix multiply functions, and then assembled in a future step. However, handling the bandwidth requirements between processing cores can limit network training time and inference performance.

Multiple approaches have been used to increase memory bandwidth including using Static DRAM (SDRAM), Double data rate DRAM (DDR), and so on. The example 1500 shows an AI accelerator card 0 1510. The accelerator includes an AI accelerator 1512. The AI accelerator can include processing cores, custom cores, matrix multiply units, multiply accumulators (MACs), and so on. The AI accelerator can be designed to specifically increase the speed of matrix multiply and other functions associated with the neural network. The AI accelerator card can include DDR memory 1514. The DDR memory can be DDR1, DDR2, DDR3, DDR4, DDR5, and so on. While each generation of DDR memory has improved bandwidth, the memory chips communicate with the AI accelerator only via the AI accelerator card. The DDR memory can comprise any type of memory. While the memory can be physically close to the accelerator, signals must still travel off a silicon die, through a package, across the board, and through another package to the destination die. This can require long cycle times in comparison to the speed of the memory chips and/or AI processors. In addition, the width of the memory buses to and from the AI accelerator chips can be limited due to the need to interface between multiple physical packages.

An improvement in bandwidth can be achieved by 2.5D technology. The example 1500 shows an example of 2.5D technology in AI accelerator card 1 1520. In this case, high bandwidth memory (HBM) 1522 can be included on the same silicon interposer 1524 as the AI accelerator 1526. As shown in 1530, two DRAM dies 1540 can be stacked within the HBM memory. In practice, any number of DRAM dies can be stacked. The DRAM chips can communicate with each other and to a memory controller 1550 via through-silicon vias (TSVs) 1542. Although example 1500 shows DRAM chips, in practice, any type of memory chip can be coupled with 2.5D technology, including LPDDR, GDDR, SRAM, VRAM chips, and so on. The controller and the AI accelerator 1560 can be coupled to the same silicon interposer 1570. The coupling can include micro-bumps, controlled collapse chip connections (C4s), and so on. Communications between the memory controller and the AI accelerator can therefore be accomplished within metal layers of the silicon interposer, improving latency, signal integrity, and/or bandwidth as many more wires can be established within the silicon wafer than would have been possible with a typical packaging interface as shown in 1510. Thus, an extremely high bandwidth bus between the memory and AI accelerator can be established. The silicon interposer can be coupled to a substrate 1580 which can be soldered to AI accelerator card 1. This memory implementation can improve a local bandwidth path between memory to a single AI accelerator (which can include many processors). However, for larger neural networks, bandwidth improvements are also required at the system level between multiple AI accelerators.

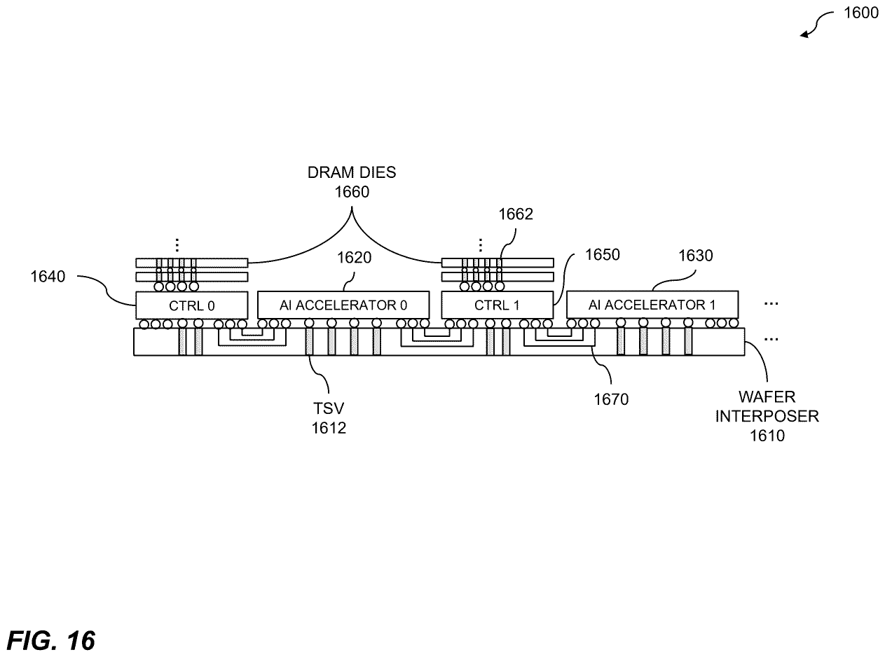

FIG. 16 is a cross-section of wafer scale integration for neural network memory bandwidth. As described above, the need for memory bandwidth, especially for large neural networks, can be performance limiting. While memory technology such as 2.5D can improve local memory bandwidth, system-wide memory bandwidth is still a significant technical challenge. Wafer scale integration can significantly improve these bandwidth requirements. The cross-section 1600 shows a wafer interposer 1610. The wafer interposer can comprise a 300 mm wafer, a 200 mm wafer, and so on. The wafer interposer can include any number of through-silicon vias (TSVs) 1612. The TSVs can enable communications between the front side and the back side of the wafer. To reliably process the TSVs, the back side of the wafer can be polished, ground, and so on. A plurality of AI accelerators, such as AI accelerator 0 1620 and AI accelerator 1 1630 can be coupled to the wafer interposer. The coupling can include micro-bumps, C4s, and so on. The AI accelerators can be coupled to a plurality of memory controllers, such as memory controller 1640, 1650, and so on. The memory controllers can be based on SDRAM, DDR1, DDR2, DDR3, DDR4, DDR5, HBM, and so on. The memory controllers can be coupled to any number of memory chips. The memory chips can be based on 2.5D technology, which can enable stacking of one or more memory dies 1660. The memory dies can communicate to other memory dies and to the respective controller by TSVs 1662. The memory can be coupled to one or more AI accelerators by wiring paths 1670 within the wafer interposer. Though AI accelerators and memory chips are shown in cross-section 1600, in practice any type of chips can be included including processors, system-on-chips (SoCs), application-specific integrations circuits (ASICs), and so on. The wafer interposer can be processed using a back-end-of-line (BEOL) wafer process which can include any number of metal layers. These metal layers can be used to couple any AI accelerator to any memory controller. The wafer metal layers can provide extremely high bandwidth between any memory controller and any AI processor on the wafer.

The wafer scale integration approach shown in FIG. 16 can address the system level bandwidth requirements necessary for larger neural networks. Recall that neural networks with parameter sizes into the billions or trillions can require significant memory for the model. Recall also that training a large neural network can require a number of training images that can be ten times (or more) the number of parameters. Each of these models must be presented to the network for a forward and back-propagation training pass. Multiple intermediate sets of weights and biases for each node in the neural network can also be stored and maintained through the training process. Further, because the matrix functions for larger neural networks are far too large for any single processor, the processing mentioned above can be divided and sent to many processors, and can span many chips, cards, server racks, or even data centers. While adding additional processors can be straightforward (though expensive), keeping those processors efficiently running can be an extremely difficult task, often gated by memory bandwidth as relevant data must be sent to every processor, regardless of location. Wafer scale integration can reduce bandwidth bottlenecks between many AI accelerators (which can comprise many processor cores, specialized AI cores, accelerators, and so on) and significant amounts of memory. As a result, an entire medium to large size neural network can be fully trained and can run interferences on a single wafer interposer. For larger models, such as ChatGPT, any number of wafer interposers can be coupled together to provide a significant improvement in bandwidth and computation speed.

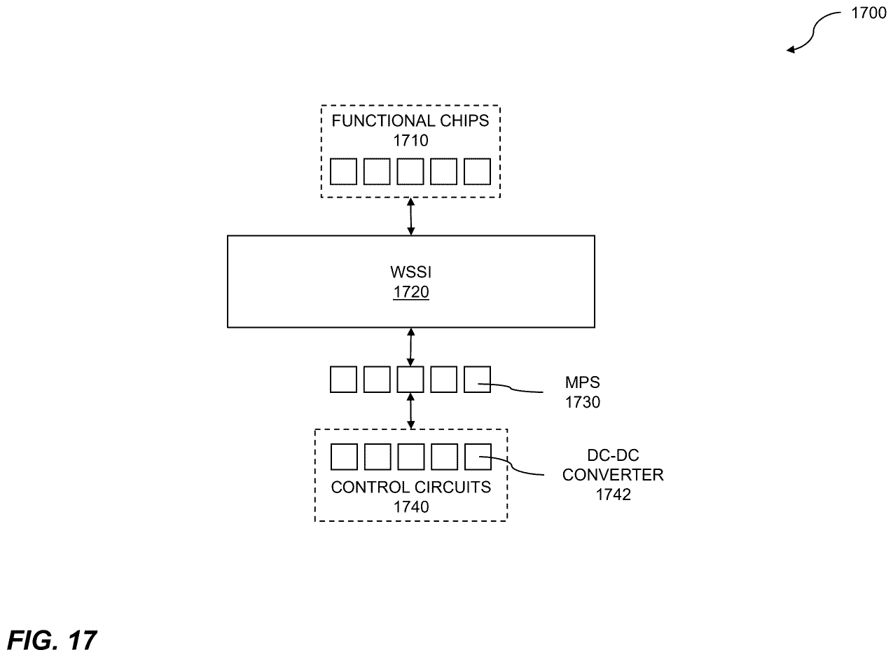

FIG. 17 is a system diagram for back side wafer-scale integration with modular power delivery. The system can accomplish wafer-scale integration (WSI) by using a wafer-scale silicon interposer (WSSI). The interposer can be based on an organic substrate or on an inorganic substrate. The WSSI can be used to mount chips such as functional chips to a side such as a top side of the WSSI. The WSSI can further be used to connect modules such as modular power substrates (MPS) to a side such as a bottom or back side of the WSSI. The WSSI provides conduction paths such as through-silicon vias (TSVs), which can provide connections between pads associated with the functional chips and pads associated with the MPSs. The WSSI can further include one or more layers of interconnect separated by layers of insulation. The one or more layers of interconnect can enable connections between and among functional chips, between and among MPSs, and so on. Further, the WSSI can include a material with a coefficient of expansion where mechanical connections to the WSSI accommodate a maximum lateral displacement, thereby maintaining reliable connections and minimizing risk of disconnects or damage to the functional chips or to the MPSs. The back side wafer-scale integration with modular power delivery enables power delivery to the functional parts.

The system 1700 can include a system for power delivery comprising: a wafer-scale silicon interposer (WSSI), wherein a front side of the WSSI is bonded to a plurality of functional chips, and wherein the WSSI includes a plurality of through-silicon vias (TSVs); a plurality of modular power substrates (MPSs), wherein the plurality of MPSs is based on a form factor mirroring one or more corresponding functional chips, within the plurality of functional chips, on the front side of the WSSI, and wherein the plurality of MPSs is attached to a back side of the WSSI; one or more control circuits, wherein the one or more control circuits include a plurality of DC-to-DC power converters, and wherein each DC-to-DC power converter in the plurality of DC-to-DC power converters includes a mechanical connection to a respective MPS in the plurality of MPSs, wherein the system, when provided DC power, is configured to: send DC power, by the one or more control circuits, to the plurality of MPSs, wherein the sending includes a first voltage conversion; and transfer the DC power that was sent, by the plurality of MPSs, to the plurality of functional chips, wherein the transferring is based on the plurality of TSVs.

The system 1700 can include one or more functional chips 1710. The functional chips can include general purpose chips such as processors, multiprocessors, memories, switches, and network controllers, and so on. The functional chips can include substantially similar chips or a mix of two or more types of chips. The functional chips can include chips for executing applications that process large amounts of data. The functional chips can include chips with architectures that are appropriate for handling applications such as image processing, audio processing, natural language processing, and so on. The functional chips can include chips for artificial intelligence applications such as machine learning applications. The functional chips can include memory chips such as DRAM, SRAM, and so on. The functional chips can be configured such that the chips can be mounted to a substrate or interposer such as a wafer-scale silicon interposer. The functional chips can be connected to the WSSI using a flip chip technique. A flip chip technique is enabled by locating connections to the chip on the topmost layer of the chips. Micro-bumps of solder can be placed on the pads associated with the chip connections. The chips are then flipped and the micro-bumps heated to mechanically connect the flipped chips to a substrate, a board such as a circuit board, an interposer, etc.

The system 1700 can include a wafer-scale silicon interposer (WSSI) 1720. The WSSI can provide a substrate to which the functional chips can be bonded using techniques such as the flip-chip technique described previously. The functional chips can be bonded to a side of the WSSI. In embodiments, a front side of the WSSI is bonded to a plurality of functional chips. Interconnect can be provided by the WSSI to enable communications between and among the functional chips. In embodiments, the WSSI includes one or more optical waveguides. The optical waveguides can enable chip-to-chip communication via light. The optical waveguides can comprise buses and control signals between chips.

Connections can be provided between sides of the WSSI. In embodiments, the WSSI can include a plurality of through-silicon vias (TSVs). The TSVs can enable connections between the functional chips on the front side of the WSSI and elements connected to the back side of the WSSI. The WSSI can comprise one or more materials that are suited to serving as a substrate to the functional chips. While silicon can be used for the interposer, other inorganic materials such as glass can also be used. The glass can include a type of glass that possesses a coefficient of expansion that is compatible with the functional chips. A compatible coefficient of expansion can include a coefficient of expansion that is substantially similar to the coefficient of expansion of the functional chips and other elements bonded to or mechanically connected to the WSSI. A compatible coefficient of expansion can accommodate a maximum lateral displacement thereby enabling reliable connections and minimizing risk of damage to functional chips, the WSSI, and mechanically connected elements.

The system 1700 can include a plurality of modular power substrates (MPSs) 1730. The plurality of MPSs can be attached to the side of the WSSI opposite to the side of the WSSI with the bonded plurality of functional chips. In embodiments, the MPSs are attached to a back side of the WSSI in such a way as to be coupled with the functional chips described previously. In embodiments, each MPS can be coupled to one or more functional chips within the plurality of functional chips. The coupling can be accomplished using the TSV described previously, interconnect from among the multilayer interconnect, and so on. The MPSs can be configured based on a form factor. In embodiments, the plurality of MPSs is based on a form factor mirroring one or more corresponding functional chips, within the plurality of functional chips, on the front side of the WSSI. The form factor can be chosen based on a coefficient of expansion. The MPSs can include a substrate. In embodiments, one or more MPSs within the plurality of MPSs comprise an organic substrate. The organic substrate materials can include paper cores impregnated with phenolic resin; woven or unwoven glass cloth impregnated with epoxy or cyanate ester among others; natural fibers; etc. In other embodiments, one or more MPSs within the plurality of MPSs comprise an inorganic substrate. An inorganic substrate can be based on silicon, glass with a similar coefficient of expansion to the MPS, etc.

The system 1700 can include one or more mechanically connected control circuits 1740. The mechanical connections can be accomplished using plug and socket techniques. In embodiments, the mechanical connections are based on a high voltage socket. The high voltage socket can handle a high current, high DC voltage. In embodiments, the one or more control circuits can include one or more control boards. The one or more control boards can be used to send DC power to the plurality of MPSs. The one or more control boards can include individual control boards, or the individual control boards can be combined. In embodiments, the one or more control boards can comprise a unified control board (UCB). The connecting mechanically the one or more control boards can take into account different coefficients of expansion between the MPSs, the WSSI, the unified control board, and so on. In embodiments, the connecting mechanically can accommodate a maximum lateral displacement of the UCB due to thermal expansion during operation. The taking into account the maximum lateral displacement of the UCB can enable reliable mechanical connections, reducing the risk of damage to the MPSs, the WSSI, and the UCB due to different amounts of expansion while operating, etc. Other coefficients of thermal expansion can also be considered. In other embodiments, a coefficient of thermal expansion of the UCB is different than a coefficient of thermal expansion of the WSSI. Further connectors can be used to establish connections between an MPS and a controller such as a digital controller chip. Further embodiments can include electrically coupling the digital controller chip to the plurality of MPSs, wherein the coupling is based on a plurality of rigid-flex strips. One or more rigid-flex strips can be mounted to the MPS. The rigid-flex strips can provide control signals from the digital controller chip to the MPS. In embodiments, the plurality of rigid-flex strips can include one or more power control signals. The power control signals can enable or disable one or more MPSs, can control the DC-to-DC converters, and so on. In embodiments, the plurality of rigid-flex strips can include at least a portion of the DC power that was transferred. The rigid-flex strip can handle differences in coefficients of thermal expansion between the controller and the MPS.

In the system 1700, the one or more control circuits include a plurality of DC-to-DC power converters 1742. The DC-to-DC power converters can convert between DC voltages. When the DC output voltage is lower than the DC input voltage, then the DC-to-DC converter can include a buck converter. When the DC output voltage is higher than the DC input voltage, then the DC-to-DC converter can include a boost converter. Further embodiments include enabling power control, by a digital controller chip, of the plurality of MPSs. DC power can be fed to the UCB. Embodiments can include feeding the DC power, by one or more high current bus bars, to the UCB. The high current bus bars can include one or more of a positive DC bus bar and a negative DC bus bar. The DC-to-DC converters can convert an input DC voltage to an output DC voltage. A number of DC-to-DC voltage conversions are possible. In embodiments, the first voltage conversion can be accomplished by the plurality of DC-to-DC power converters. In embodiments, a voltage range of the DC power that was fed can include a first voltage range. The first voltage range can include a high DC voltage range. In embodiments, the first voltage range is 48 volts to 54 volts, inclusive. Other DC voltage ranges can be included, depending on availability of voltage ranges for the first voltage. In embodiments, the sending can include altering, by the plurality of MPSs, the DC power that was sent, wherein the altering is based on a second voltage conversion. The second voltage conversion can include conversion of the first voltage to a higher second voltage or to a lower second voltage. In embodiments, the second voltage conversion can result in a voltage less than a threshold. The threshold can include a target voltage, a functional chip operating voltage, and the like. In embodiments, the threshold can be 1 volt. The second voltage can include a second voltage range. In embodiments, the second voltage range can be 12 volts to 13.5 volts, inclusive.

Each of the above methods may be executed on one or more processors on one or more computer systems. Embodiments may include various forms of distributed computing, client/server computing, and cloud-based computing. Further, it will be understood that the depicted steps or boxes contained in this disclosure's flow charts are solely illustrative and explanatory. The steps may be modified, omitted, repeated, or re-ordered without departing from the scope of this disclosure. Further, each step may contain one or more sub-steps. While the foregoing drawings and description set forth functional aspects of the disclosed systems, no particular implementation or arrangement of software and/or hardware should be inferred from these descriptions unless explicitly stated or otherwise clear from the context. All such arrangements of software and/or hardware are intended to fall within the scope of this disclosure.

The block diagrams and flowchart illustrations depict methods, apparatus, systems, and computer program products. The elements and combinations of elements in the block diagrams and flow diagrams show functions, steps, or groups of steps of the methods, apparatus, systems, computer program products and/or computer-implemented methods. Any and all such functions—generally referred to herein as a “circuit,” “module,” or “system” may be implemented by computer program instructions, by special-purpose hardware-based computer systems, by combinations of special purpose hardware and computer instructions, by combinations of general-purpose hardware and computer instructions, and so on.

A programmable apparatus which executes any of the above-mentioned computer program products or computer-implemented methods may include one or more microprocessors, microcontrollers, embedded microcontrollers, programmable digital signal processors, programmable devices, programmable gate arrays, programmable array logic, memory devices, application specific integrated circuits, or the like. Each may be suitably employed or configured to process computer program instructions, execute computer logic, store computer data, and so on.

It will be understood that a computer may include a computer program product from a computer-readable storage medium and that this medium may be internal or external, removable and replaceable, or fixed. In addition, a computer may include a Basic Input/Output System (BIOS), firmware, an operating system, a database, or the like that may include, interface with, or support the software and hardware described herein.

Embodiments of the present invention are limited to neither conventional computer applications nor the programmable apparatus that run them. To illustrate: the embodiments of the presently claimed invention could include an optical computer, quantum computer, analog computer, or the like. A computer program may be loaded onto a computer to produce a particular machine that may perform any and all of the depicted functions. This particular machine provides a means for carrying out any and all of the depicted functions.

Any combination of one or more computer readable media may be utilized including but not limited to: a non-transitory computer readable medium for storage; an electronic, magnetic, optical, electromagnetic, infrared, or semiconductor computer readable storage medium or any suitable combination of the foregoing; a portable computer diskette; a hard disk; a random access memory (RAM); a read-only memory (ROM); an erasable programmable read-only memory (EPROM, Flash, MRAM, FeRAM, or phase change memory); an optical fiber; a portable compact disc; an optical storage device; a magnetic storage device; or any suitable combination of the foregoing. In the context of this document, a computer readable storage medium may be any tangible medium that can contain or store a program for use by or in connection with an instruction execution system, apparatus, or device.

It will be appreciated that computer program instructions may include computer executable code. A variety of languages for expressing computer program instructions may include without limitation C, C++, Java, JavaScript™, ActionScript™, assembly language, Lisp, Perl, Tcl, Python, Ruby, hardware description languages, database programming languages, functional programming languages, imperative programming languages, and so on. In embodiments, computer program instructions may be stored, compiled, or interpreted to run on a computer, a programmable data processing apparatus, a heterogeneous combination of processors or processor architectures, and so on. Without limitation, embodiments of the present invention may take the form of web-based computer software, which includes client/server software, software-as-a-service, peer-to-peer software, or the like.

In embodiments, a computer may enable execution of computer program instructions including multiple programs or threads. The multiple programs or threads may be processed approximately simultaneously to enhance utilization of the processor and to facilitate substantially simultaneous functions. By way of implementation, any and all methods, program codes, program instructions, and the like described herein may be implemented in one or more threads which may in turn spawn other threads, which may themselves have priorities associated with them. In some embodiments, a computer may process these threads based on priority or other order.

Unless explicitly stated or otherwise clear from the context, the verbs “execute” and “process” may be used interchangeably to indicate execute, process, interpret, compile, assemble, link, load, or a combination of the foregoing. Therefore, embodiments that execute or process computer program instructions, computer-executable code, or the like may act upon the instructions or code in any and all of the ways described. Further, the method steps shown are intended to include any suitable method of causing one or more parties or entities to perform the steps. The parties performing a step, or portion of a step, need not be located within a particular geographic location or country boundary. For instance, if an entity located within the United States causes a method step, or portion thereof, to be performed outside of the United States, then the method is considered to be performed in the United States by virtue of the causal entity.

While the invention has been disclosed in connection with preferred embodiments shown and described in detail, various modifications and improvements thereon will become apparent to those skilled in the art. Accordingly, the foregoing examples should not limit the spirit and scope of the present invention; rather it should be understood in the broadest sense allowable by law.

What is claimed is:

1. A method for power delivery comprising:
accessing a wafer-scale silicon interposer (WSSI), wherein a front side of the WSSI is bonded to a plurality of functional chips, and wherein the WSSI includes a plurality of through-silicon vias (TSVs);
attaching, to a back side of the WSSI, a plurality of modular power substrates (MPSs), wherein each MPS is coupled to one or more functional chips within the plurality of functional chips;
connecting mechanically the plurality of MPSs, to one or more control circuits, wherein the one or more control circuits include a plurality of DC-to-DC power converters;
sending DC power, by the one or more control circuits, to the plurality of MPSs, wherein the sending includes a first voltage conversion; and
transferring the DC power that was sent, by the plurality of MPSs, to the plurality of functional chips, wherein the transferring is based on the plurality of TSVs.

2. The method of claim 1 wherein the plurality of MPSs is based on a form factor mirroring one or more corresponding functional chips, within the plurality of functional chips, on the front side of the WSSI.

3. The method of claim 1 wherein the one or more control circuits comprise one or more control boards.

4. The method of claim 3 wherein the one or more control boards comprise a unified control board (UCB).

5. The method of claim 4 wherein the connecting mechanically accommodates a maximum lateral displacement of the UCB due to thermal expansion during operation.

6. The method of claim 5 wherein a coefficient of thermal expansion of the UCB is different than a coefficient of thermal expansion of the WSSI.

7. The method of claim 5 further comprising matching each DC-to-DC power converter within the plurality of DC-to-DC power converters included on the UCB to one or more respective MPSs in the plurality of MPSs.

8. The method of claim 4 further comprising feeding the DC power, by one or more high current bus bars, to the UCB.

9. The method of claim 8 wherein a voltage range of the DC power that was fed comprises a first voltage range.

10. The method of claim 1 wherein the sending includes altering, by the plurality of MPSs, the DC power that was sent, wherein the altering is based on a second voltage conversion.

11. The method of claim 10 wherein the second voltage conversion results in a voltage less than a threshold.

12. The method of claim 11 wherein the first voltage conversion results in a second voltage range.

13. The method of claim 1 wherein the WSSI includes one or more optical waveguides.

14. The method of claim 1 further comprising enabling power control, by a digital controller chip, of the plurality of MPSs.

15. The method of claim 14 further comprising electrically coupling the digital controller chip to the plurality of MPSs, wherein the coupling is based on a plurality of rigid-flex strips.

16. The method of claim 15 wherein the plurality of rigid-flex strips includes one or more power control signals.

17. The method of claim 1 wherein the first voltage conversion is accomplished by the plurality of DC-to-DC power converters.

18. The method of claim 1 wherein the attaching is based on one or more controlled collapse chip connection bumps (C4s).

19. The method of claim 1 wherein the connecting mechanically is based on a high voltage socket.

20. An apparatus for power delivery comprising:
a wafer-scale silicon interposer (WSSI), wherein a front side of the WSSI is bonded to a plurality of functional chips, and wherein the WSSI includes a plurality of through-silicon vias (TSVs);
a plurality of modular power substrates (MPSs), wherein the plurality of MPSs is based on a form factor mirroring one or more corresponding functional chips, within the plurality of functional chips, on the front side of the WSSI, and wherein the plurality of MPSs is attached to a back side of the WSSI; and
one or more control circuits, wherein the one or more control circuits include a plurality of DC-to-DC power converters, and wherein each DC-to-DC power converter in the plurality of DC-to-DC power converters includes a mechanical connection to a respective MPS in the plurality of MPSs.

21. The apparatus of claim 20 wherein the one or more control circuits comprises one or more control boards.

22. The apparatus of claim 21 wherein the one or more control boards comprise a unified control board (UCB).

23. The apparatus of claim 22 wherein the mechanical connection accommodates a maximum lateral displacement of the UCB due to thermal expansion during operation.

24. The apparatus of claim 22 wherein the mechanical connection is based on a high voltage socket, wherein the high voltage socket transfers power from the UCB to the plurality of MPSs.

25. The apparatus of claim 22 wherein the UCB includes a digital controller chip, and wherein the digital controller chip controls power delivery to the plurality of functional chips.

26. The apparatus of claim 25 wherein the mechanical connection includes a plurality of rigid-flex strips.

27. The apparatus of claim 26 wherein the plurality of rigid-flex strips includes one or more power control signals from the digital controller chip to the plurality of MPSs.

28. The apparatus of claim 20 further comprising one or more high current bus bars, wherein the one or more high current bus bars are coupled to the one or more control circuits.

29. A system for power delivery comprising:
a wafer-scale silicon interposer (WSSI), wherein a front side of the WSSI is bonded to a plurality of functional chips, and wherein the WSSI includes a plurality of through-silicon vias (TSVs);
a plurality of modular power substrates (MPSs), wherein the plurality of MPSs is based on a form factor mirroring one or more corresponding functional chips, within the plurality of functional chips, on the front side of the WSSI, and wherein the plurality of MPSs is attached to a back side of the WSSI;
one or more control circuits, wherein the one or more control circuits include a plurality of DC-to-DC power converters, and wherein each DC-to-DC power converter in the plurality of DC-to-DC power converters includes a mechanical connection to a respective MPS in the plurality of MPSs, wherein the system, when provided DC power, is configured to:
send DC power, by the one or more control circuits, to the plurality of MPSs, wherein the sending includes a first voltage conversion; and
transfer the DC power that was sent, by the plurality of MPSs, to the plurality of functional chips, wherein the transferring is based on the plurality of TSVs.
